(19) United States
(12) Patent Application Publication
(10) Pub. No.: US 2024/0371847 A1
(43) Pub. Date: Nov. 7, 2024

(54) LIGHT-EMITTING SUBSTRATE AND METHOD FOR MANUFACTURING THE SAME, AND DISPLAY APPARATUS

(71) Applicants: BEIJING BOE TECHNOLOGY DEVELOPMENT CO., LTD., Beijing (CN); BOE TECHNOLOGY GROUP CO., LTD., Beijing (CN)

(72) Inventors: Shuilang DONG, Beijing (CN); Yan QU, Beijing (CN); Xinhong LU, Beijing (CN); Zhanfeng CAO, Beijing (CN); Guoteng LI, Beijing (CN); Liuqing LI, Beijing (CN)

(73) Assignees: BEIJING BOE TECHNOLOGY DEVELOPMENT CO., LTD., Beijing (CN); BOE TECHNOLOGY GROUP CO., LTD., Beijing (CN)

(21) Appl. No.: 18/772,282

(22) Filed: Jul. 15, 2024

Related U.S. Application Data
(63) Continuation of application No. PCT/CN2023/089352, filed on Apr. 19, 2023.

(51) Int. Cl. H01L 25/16; H01L 25/075; H01L 33/06; H01L 33/10; H01L 33/38; H01L 33/62

(52) U.S. Cl. CPC H01L 25/167; H01L 25/0753; H01L 33/06; H01L 33/10; H01L 33/38; H01L 33/62; H01L 2933/0016; H01L 2933/0066

(57) ABSTRACT

A light-emitting substrate includes a driving circuit layer, a first light-emitting layer located on a side of the driving circuit layer, a second light-emitting layer located on a side of the first light-emitting layer away from the driving circuit layer, and a third light-emitting layer located on a side of the second light-emitting layer away from the driving circuit layer. The pixel circuit layer includes pixel circuits. The first light-emitting layer includes first light-emitting devices respectively coupled to the pixel circuits. The second light-emitting layer includes second light-emitting devices respectively coupled to the pixel circuits. The third light-emitting layer includes third light-emitting devices respectively coupled to the pixel circuits. Orthographic projections of a first light-emitting device, a second light-emitting device and a third light-emitting device on the driving circuit layer do not necessarily coincide with each other.

### CROSS-REFERENCE TO RELATED APPLICATION

This application is a Bypass Continuation Application of International Patent Application No. PCT/CN2023/089352, filed on Apr. 19, 2023, which is incorporated herein by reference in its entirety.

### TECHNICAL FIELD

The present disclosure relates to the field of display technologies, and in particular, to a light-emitting substrate, a method for manufacturing a light-emitting substrate, and a display apparatus.

### BACKGROUND

A light-emitting diode (LED) is a type of semiconductor diode, and is a kind of optoelectronic element that emit light relying on the unidirectional conductivity of the semiconductor PN junction. LEDs are lighting elements widely used in the world market, have advantages such as small volume, high brightness, low power consumption, low heat generation, long service life, and environmental protection, and have a rich variety of colors, thus being deeply loved by consumers.

With the development of LED technology, micro light-emitting diodes (Micro LEDs) and mini light-emitting diodes (Mini LEDs) have also been gradually developed.

### SUMMARY

In an aspect, a light-emitting substrate is provided. The light-emitting substrate includes a driving circuit layer, a first light-emitting layer, a second light-emitting layer, and a third light-emitting layer. The driving circuit layer includes a plurality of pixel circuits. The first light-emitting layer is located on a side of the driving circuit layer. The first light-emitting layer includes a plurality of first light-emitting devices, and the plurality of first light-emitting devices are respectively coupled to the plurality of pixel circuits. The second light-emitting layer is located on a side of the first light-emitting layer away from the driving circuit layer. The second light-emitting layer includes a plurality of second light-emitting devices, and the plurality of second light-emitting devices are respectively coupled to the plurality of pixel circuits. The third light-emitting layer is located on a side of the second light-emitting layer away from the driving circuit layer. The third light-emitting layer includes a plurality of third light-emitting devices, and the plurality of third light-emitting devices are respectively coupled to the plurality of pixel circuits. A color of light emitted by the first light-emitting devices, a color of light emitted by the second light-emitting devices, and a color of light emitted by the third light-emitting devices are different from each other. An orthographic projection of a first light-emitting device on the driving circuit layer, an orthographic projection of a second light-emitting device on the driving circuit layer, an orthographic projection of a third light-emitting device on the driving circuit layer do not necessarily coincide with each other.

In some embodiments, the first light-emitting layer includes first auxiliary electrode patterns, and an anode or cathode of the first light-emitting device is coupled to a first auxiliary electrode pattern.

In some embodiments, the second light-emitting layer includes second auxiliary electrode patterns, and an anode or cathode of the second light-emitting device is coupled to a second auxiliary electrode pattern.

In some embodiments, the third light-emitting layer includes third auxiliary electrode patterns, and an anode or cathode of the second light-emitting device is coupled to a third auxiliary electrode pattern.

In some embodiments, the light-emitting substrate includes the first auxiliary electrode patterns, the second auxiliary electrode patterns, and the third auxiliary electrode patterns. An area of the third auxiliary electrode pattern is greater than an area of the second auxiliary electrode pattern, and the area of the second auxiliary electrode pattern is greater than an area of the first auxiliary electrode pattern.

In some embodiments, the light-emitting substrate includes the first auxiliary electrode patterns, the second auxiliary electrode patterns, and the third auxiliary electrode patterns. An orthographic projection of the second auxiliary electrode pattern on the driving circuit layer at least partially coincides with an orthographic projection of the first auxiliary electrode pattern on the driving circuit layer. And/or, an orthographic projection of the third auxiliary electrode pattern on the driving circuit layer at least partially coincides with the orthographic projection of the second auxiliary electrode pattern on the driving circuit layer.

In some embodiments, the first light-emitting layer includes 3N first conductive pillars, the second light-emitting layer includes 2N second conductive pillars, the third light-emitting layer includes N third conductive pillars. The first conductive pillars, the second conductive pillars and the third conductive pillars all extend in a direction perpendicular to the driving circuit layer. N first conductive pillars constitute N first conductive structures, and each of the first conductive structures is connected to the driving circuit layer and a first light-emitting device. Another N first conductive pillars and N second conductive pillars are connected in one-to-one correspondence and together constitute N second conductive structures, and each of the second conductive structures is connected to the driving circuit layer and a second light-emitting device. Remaining N first conductive pillars and another N second conductive pillars are connected in one-to-one correspondence, and the another N second conductive pillars and the N third conductive pillars are connected in one-to-one correspondence; the remaining N first conductive pillars, the another N second conductive pillars and the N third conductive pillars together constitute N third conductive structures; and each of the third conductive structures is connected to the driving circuit layer and a third light-emitting device.

In some embodiments, the first light-emitting layer includes first reflective films, and a first reflective film covers side surfaces of the first light-emitting device perpendicular to the driving circuit layer and a surface of the first light-emitting device proximate to the driving circuit layer.

In some embodiments, the second light-emitting layer includes second reflective films, and a second reflective film covers side surfaces of the second light-emitting device perpendicular to the driving circuit layer and a surface of the second light-emitting device proximate to the driving circuit layer.

In some embodiments, the third light-emitting layer includes third reflective films, and a third reflective film covers side surfaces of the third light-emitting device perpendicular to the driving circuit layer and a surface of the third light-emitting device proximate to the driving circuit layer.

In some embodiments, the light-emitting substrate includes the first reflective films, the second reflective films, and the third reflective films. A wavelength of the color of the light emitted by the first light-emitting devices is less than a wavelength of the color of the light emitted by the second light-emitting devices, and the wavelength of the color of the light emitted by the second light-emitting devices is less than a wavelength of the color of the light emitted by the third light-emitting devices. A thickness of the first reflective film is less than a thickness of the second reflective film, and the thickness of the second reflective film is less than a thickness of the third reflective film.

In some embodiments, an anode of the first light-emitting device is located on a side of a cathode of the first light-emitting device proximate to the driving circuit layer, and/or an anode of the second light-emitting device is located on a side of a cathode of the second light-emitting device proximate to the driving circuit layer. A cathode of the third light-emitting device is located on a side of an anode of the third light-emitting device proximate to the driving circuit layer.

In some embodiments, the orthographic projection of the first light-emitting device on the driving circuit layer overlaps with the orthographic projection of the second light-emitting device on the driving circuit layer.

In some embodiments, the orthographic projection of the second light-emitting device on the driving circuit layer overlaps with the orthographic projection of the third light-emitting device on the driving circuit layer.

In some embodiments, the orthographic projection of the third light-emitting device on the driving circuit layer overlaps with the orthographic projection of the first light-emitting device on the driving circuit layer.

In another aspect, a display apparatus is provided. The display apparatus includes: a light-emitting substrate and a circuit board. The circuit board is coupled to the driving circuit layer of the light-emitting substrate. The light-emitting substrate is the light-emitting substrate as described in any of the above embodiments.

In yet another aspect, a method for manufacturing a light-emitting substrate is provided. The method includes: forming a first light-emitting mother-layer on a first base, the first light-emitting mother-layer including a plurality of first light-emitting devices; forming a second light-emitting device mother-layer on a second base, the second light-emitting mother-layer including a plurality of second light-emitting devices; forming a third light-emitting mother-layer on a third base, the third light-emitting mother-layer including a plurality of third light-emitting devices;

bonding a driving circuit mother-layer to a side of the first light-emitting mother-layer away from the first base, wherein the driving circuit mother-layer includes a plurality of pixel circuits, and the plurality of pixel circuits are respectively coupled to the plurality of first light-emitting devices; removing the first base, and bonding the second light-emitting mother-layer to a side of the first light-emitting mother-layer away from the driving circuit mother-layer, wherein the plurality of second light-emitting devices are respectively coupled to the plurality of pixel circuits; removing the second base, and bonding the third light-emitting mother-layer to a side of the second light-emitting mother-layer away from the first light-emitting mother-layer, wherein the plurality of third light-emitting devices are respectively coupled to the plurality of pixel circuits; and after removing the third base, cutting the first light-emitting mother-layer, the second light-emitting mother-layer, the third light-emitting mother-layer and the driving circuit mother-layer to obtain the light-emitting substrate.

In some embodiments, forming the first light-emitting mother-layer on the first base includes: providing the first base; sequentially forming a first semiconductor mother-layer, a multiple quantum well (MQW) mother-layer and a second semiconductor mother-layer on the first base in a direction away from the first base, wherein the first semiconductor mother-layer includes a plurality of first semiconductors that are independent from each other, the MQW mother-layer includes a plurality of MQW bodies that are independent from each other, and the second semiconductor mother-layer includes a plurality of second semiconductors that are independent from each other and a second semiconductor film connecting the plurality of second semiconductors; and forming a first conductive mother-layer on a side of the second semiconductor mother-layer away from the first base, the first conductive mother-layer including a plurality of first conductors that are independent from each other. A first conductor, a first semiconductor, a MQW body, a second semiconductor and the second semiconductor film constitute a first light-emitting device.

In some embodiments, after forming the first light-emitting mother-layer, the method further includes: forming a first reflective material layer covering the first conductive mother-layer and the first base; and patterning the first reflective material layer to obtain a first reflective mother-layer. The first reflective mother-layer includes a plurality of first reflective films that are independent from each other, and a first reflective film covers a surface of the first conductor away from the first base, side surfaces of the first conductor perpendicular to the first base, side surfaces of the first semiconductor perpendicular to the first base, and side surfaces of the MQW body perpendicular to the first base, and side surfaces of the second semiconductor perpendicular to the first base.

In some embodiments, after forming the second semiconductor mother-layer, the method further includes: forming a first auxiliary electrode material layer covering the second semiconductor film; and patterning the first auxiliary electrode material layer to obtain first auxiliary electrode patterns. Orthographic projections of the first auxiliary electrode patterns on the first base are located within an orthographic projection of the second semiconductor film on the first base.

In some embodiments, after forming the plurality of first light-emitting devices that are spaced apart from each other, the method further includes: forming a first filling material layer covering the plurality of first light-emitting devices, a surface of the first filling material layer away from the first base being a flat surface; forming a plurality of first channels penetrating through the first filling material layer; and forming a first conductive pillar covering at least an inner wall of each first channel.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments of the present disclosure;

FIG. 2 is a diagram showing internal connections of a display apparatus, in accordance with some embodiments of the present disclosure;

FIG. 3 is a structural diagram of a light-emitting substrate in some solutions;

FIG. 4 is a top view of a light-emitting substrate, in accordance with some embodiments of the present disclosure;

FIG. 5 is a sectional view taken along the line A-A′ in FIG. 4;

FIG. 6 is an equivalent diagram of a pixel circuit in a light-emitting substrate, in accordance with some embodiments of the present disclosure;

FIG. 7 is an enlarged view of the first light-emitting device in FIG. 5;

FIG. 8 is an enlarged view of the second light-emitting device in FIG. 5;

FIG. 9 is an enlarged view of the third light-emitting device in FIG. 5;

FIG. 10 is another sectional view taken along the line A-A′ in FIG. 4;

FIG. 11 is a flow chart of a method for manufacturing a light-emitting substrate, in accordance with some embodiments of the present disclosure;

FIGS. 12 to 15 are diagrams showing structures of a first light-emitting mother-layer at different phases of a method for manufacturing a light-transmitting substrate, in accordance with some embodiments of the present disclosure;

FIGS. 16 to 18 are diagrams showing structures of a second light-emitting mother-layer at different phases of a method for manufacturing a light-transmitting substrate, in accordance with some embodiments of the present disclosure;

FIGS. 19 to 24 are diagrams showing structures of a first light-emitting mother-layer at different phases of a method for manufacturing a light-transmitting substrate, in accordance with some embodiments of the present disclosure;

FIG. 25 is a diagram showing a structure obtained after bonding a driving circuit layer and a first light-emitting mother-layer in a method for manufacturing a light-transmitting substrate, in accordance with some embodiments of the present disclosure;

FIG. 26 is a diagram showing a structure where the first base in FIG. 25 is removed;

FIG. 27 is a diagram showing a structure obtained after bonding a first light-emitting mother-layer and a second light-emitting mother-layer in a method for manufacturing a light-transmitting substrate, in accordance with some embodiments of the present disclosure;

FIG. 28 is a diagram showing a structure where the second base in FIG. 27 is removed;

FIG. 29 is a diagram showing a structure obtained after bonding a second light-emitting mother-layer and a third light-emitting mother-layer in a method for manufacturing a light-transmitting substrate, in accordance with some embodiments of the present disclosure;

FIG. 30 is a diagram showing a structure where the third base in FIG. 29 is removed; and

FIG. 31 is a diagram showing a structure with formed conductive protruding blocks in a method for manufacturing a light-transmitting substrate, in accordance with some embodiments of the present disclosure.

### DETAILED DESCRIPTION

The technical solutions in embodiments of the present disclosure will be described clearly and completely with reference to the accompanying drawings. However, the described embodiments are merely some but not all of embodiments of the present disclosure. All other embodiments obtained on the basis of the embodiments of the present disclosure by a person of ordinary skill in the art shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, specific features, structures, materials, or characteristics described herein may be included in any one or more embodiments or examples in any suitable manner.

Hereinafter, the terms such as “first” and “second” are used for descriptive purposes only, but are not to be construed as indicating or implying the relative importance or implicitly indicating the number of indicated technical features. Thus, features defined with “first” and “second” may explicitly or implicitly include one or more of the features. In the description of the embodiments of the present disclosure, the terms “a plurality of”, “the plurality of” and “multiple” each mean two or more unless otherwise specified.

In the description of some embodiments, the expressions “coupled” and “connected” and their derivatives may be used. The term “connected” should be understood in a broad sense. For example, the term “connected” may represent a fixed connection, or a detachable connection, or a one-piece connection; alternatively, the term “connected” may represent a direct connection, or an indirect connection through an intermediate medium. The term “coupled”, for example, indicates that two or more components are in direct physical or electrical contact. The term “coupled” or “communicatively coupled” may also indicate that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, both including following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

As used herein, depending on the context, the term “if” is optionally construed as “when”, “in a case where”, “in response to determining” or “in response to detecting”. Similarly, depending on the context, the phrase “if it is determined that” or “if [a stated condition or event] is detected” is optionally construed as “in a case where it is determined that”, “in response to determining that”, “in a case where [the stated condition or event] is detected” or “in response to detecting [the stated condition or event]”.

The phrase “applicable to” or “configured to” as used herein means an open and inclusive expression, which does not exclude devices that are applicable to or configured to perform additional tasks or steps.

In addition, the use of the phrase “based on” or “according to” is meant to be open and inclusive, since a process, step, calculation or other action that is “based on” or “according to” one or more of the stated conditions or values may, in practice, be based on or according to additional conditions or values exceeding those stated.

The term such as “about”, “substantially” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The terms “parallel”, “perpendicular” and “equal” as used herein include the stated conditions and the conditions similar to the stated conditions, and the range of the similar conditions is within the acceptable deviation range, where the acceptable deviation range is determined by a person of ordinary skill in the art in consideration of the measurement in question and the error associated with the measurement of a specific quantity (i.e., the limitation of the measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Variations in shape relative to the accompanying drawings due to, for example, manufacturing technologies and/or tolerances may be envisaged. Therefore, the exemplary embodiments should not be construed as being limited to the shapes of the regions shown herein, but including deviations due to, for example, manufacturing. For example, an etched region shown as a rectangle shape generally has a feature of being curved. Therefore, the regions shown in the accompanying drawings are schematic in nature, and their shapes are not intended to show actual shapes of regions in a device, and are not intended to limit the scope of the exemplary embodiments.

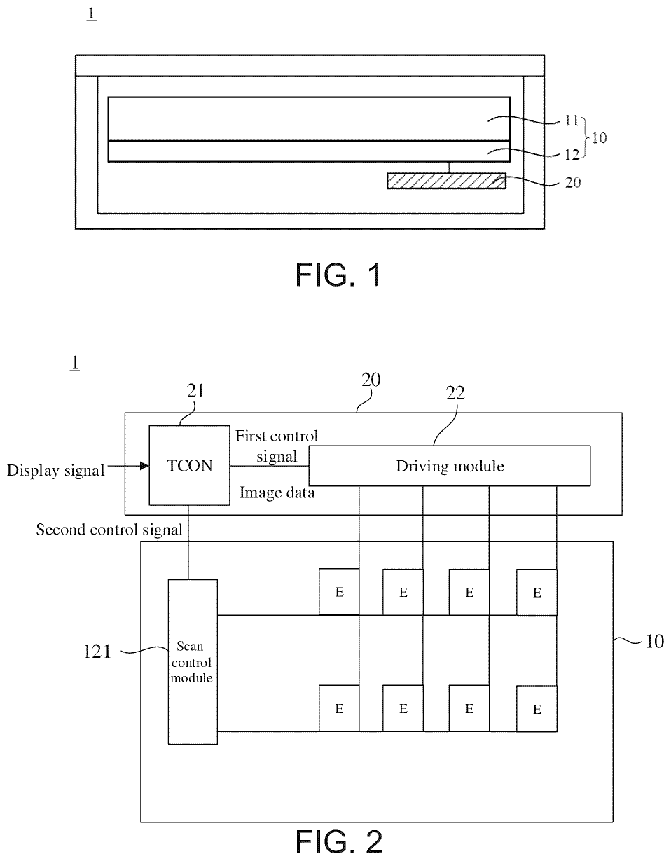

FIG. 1 is a structural diagram of a display apparatus provided in some embodiments of the present disclosure. FIG. 2 is a diagram showing internal connections of a display apparatus provided in some embodiments of the present disclosure.

As shown in FIG. 1, some embodiments of the present disclosure provide a display apparatus 1. The display apparatus 1 is a product having a function of displaying images (including an image in stationary or an image in motion (which may be a video)). For example, the display apparatus 1 may be any one of a display, a television, a billboard, a digital photo frame, a laser printer having a display function, a telephone, a mobile phone, a personal digital assistant (PDA), a digital camera, a portable camcorder, a view finder, a navigator, a vehicle, a large-area wall, a household appliance, an information inquiry device (e.g., a business inquiry device for a department of e-government, bank, hospital, electricity or the like) and a monitor.

The display apparatus 1 includes a light-emitting substrate 10 and a circuit board 20. The circuit board 20 may be located on a backlight side of the light-emitting substrate 10. The light-emitting substrate 10 is electrically connected to the circuit board 20. The light-emitting substrate 10 is configured to display images based on signals provided by the circuit board 20. The light-emitting substrate 10 includes a light-emitting layer 11 and a driving circuit layer 12 coupled to the light-emitting layer 11.

As shown in FIG. 2, the circuit board 20 includes a timing control circuit (also called a timing controller or timer control register, abbreviated as TCON) 21 and a driving module (e.g., LED driver block) 22.

The timing control circuit 21 is configured to receive display signals. The display signals include, for example, a power supply signal, a video image signal, a communication signal (e.g., a signal corresponding to an inter-integrated circuit (IIC) communication protocol) and a mode control signal (e.g., a mode control signal corresponding to a test mode or a mode control signal corresponding to a normal display mode). The video image signal is, for example, a mobile industry processor interface (MIPI) signal or a low-voltage differential signaling (LVDS) signal. The video image signal may include image data and a timing control signal. The image data includes, for example, light-emitting data of a plurality of light-emitting units. The timing control signal includes, for example, a data enable (DE) signal, a horizontal synchronization (abbreviated as Hsync or HS) signal and a vertical synchronization (abbreviated as Vsync or VS) signal.

In some embodiments, the timing control circuit 21 is further configured to, in response to the display signals, provide a first control signal and the image data to the driving module 22. The first control signal is configured to control an operation timing of the driving module 22.

The driving module 22 is configured to convert the received image data into light-emitting data signals of a plurality of light-emitting devices E (mentioned below) in the light-emitting layer 11, and sequentially output the light-emitting data signals to the light-emitting substrate 10 according to the operation timing determined by the first control signal.

The driving circuit layer 12 may include a scan control module 121 and a plurality of pixel circuits.

In some embodiments, the timing control circuit 21 is further configured to, in response to the display signals, provide a second control signal to the scan control module 121 of the driving circuit layer 12. The second control signal is configured to control an operation timing of the scan control module 121.

The scan control module 121 is configured to sequentially output scan signals to the plurality of pixel circuits at different time periods according to the operation timing determined by the second control signal, so that the light-emitting data signals are written into the plurality of pixel circuits write at different time periods, causing the plurality of light-emitting devices E corresponding the pixel circuits to emit light sequentially.

It should be noted that the first control signal and the second control signal may be different control signals. In the case where one control signal includes both the operation timing of the first control signal and the operation timing of the second control signal, the first control signal and the second control signal may be the same control signal, which is not limited here.

The light-emitting devices E in the light-emitting layer 11 may be one of mini light-emitting diodes (Mini LEDs), micro light-emitting diodes (Micro LEDs), and quantum dot light-emitting diodes (QLEDs).

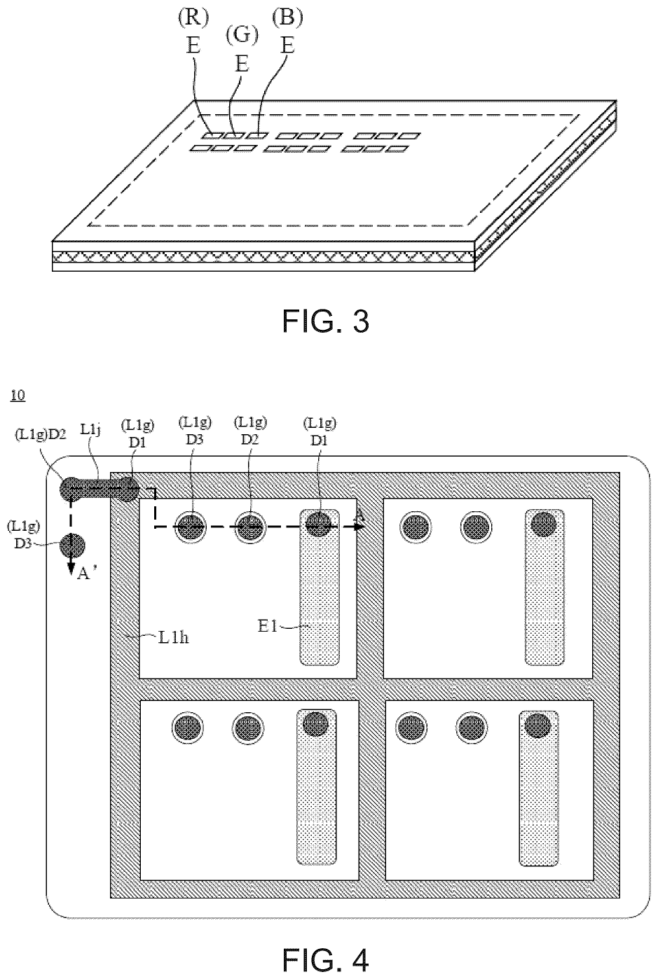

FIG. 3 is a structural diagram of a light-emitting substrate in some solutions.

The inventors of the present disclosure have found that, as shown in FIG. 3, in some solutions, after light-emitting devices E of different colors are formed on different silicon-based substrates, the light-emitting devices E of different colors are transferred to the same layer of a light-emitting substrate through mass transfer technology. There will be position errors when the light-emitting devices are transferred to the light-emitting substrate. Therefore, in order to avoid the problem of light-emitting failure caused by the overlapping of the transferred light-emitting devices E of different colors in actual products, the spacing between the light-emitting devices E of different colors will be designed to be large. In this way, after the mass transfer is finally completed, the spacing between the light-emitting devices E of different colors in the light-emitting substrate obtained is large, resulting in a problem of low resolution of the display apparatus.

In light of this, the embodiments of the present disclosure provide a light-emitting substrate to overcome the problem of large spacing between light-emitting devices E of different colors in the light-emitting substrate and improve the resolution of the display apparatus.

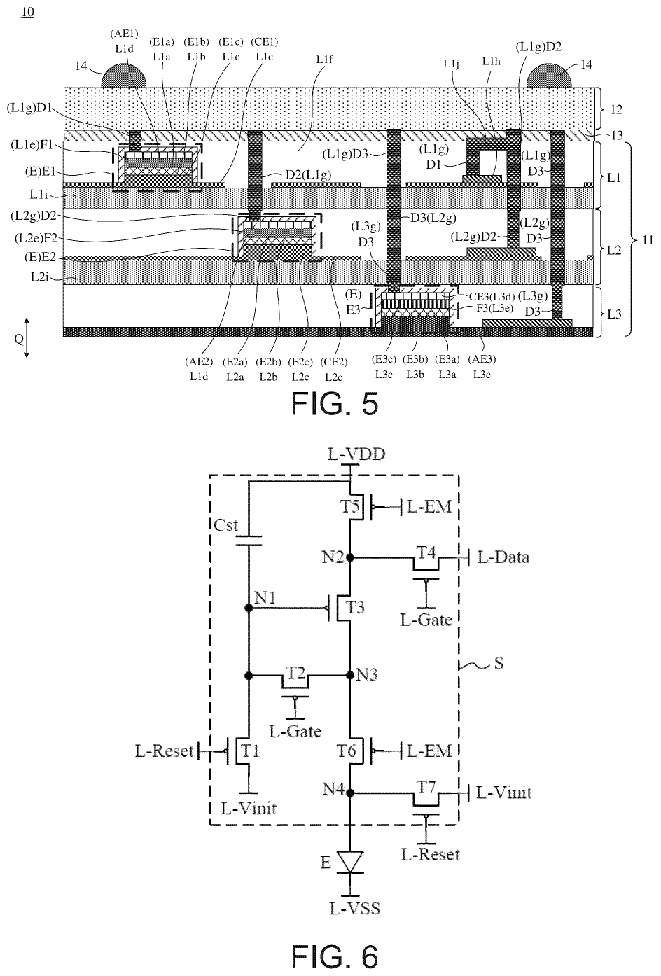

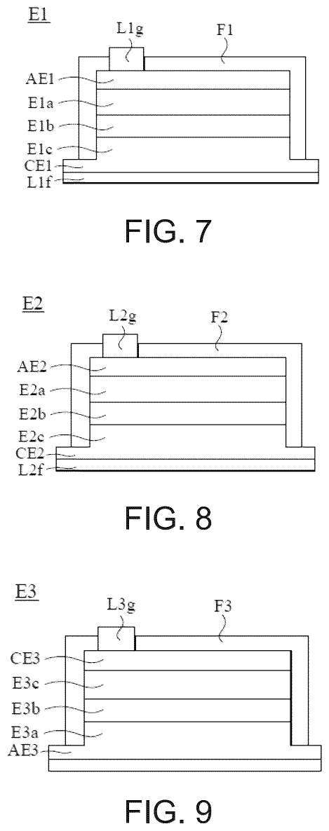

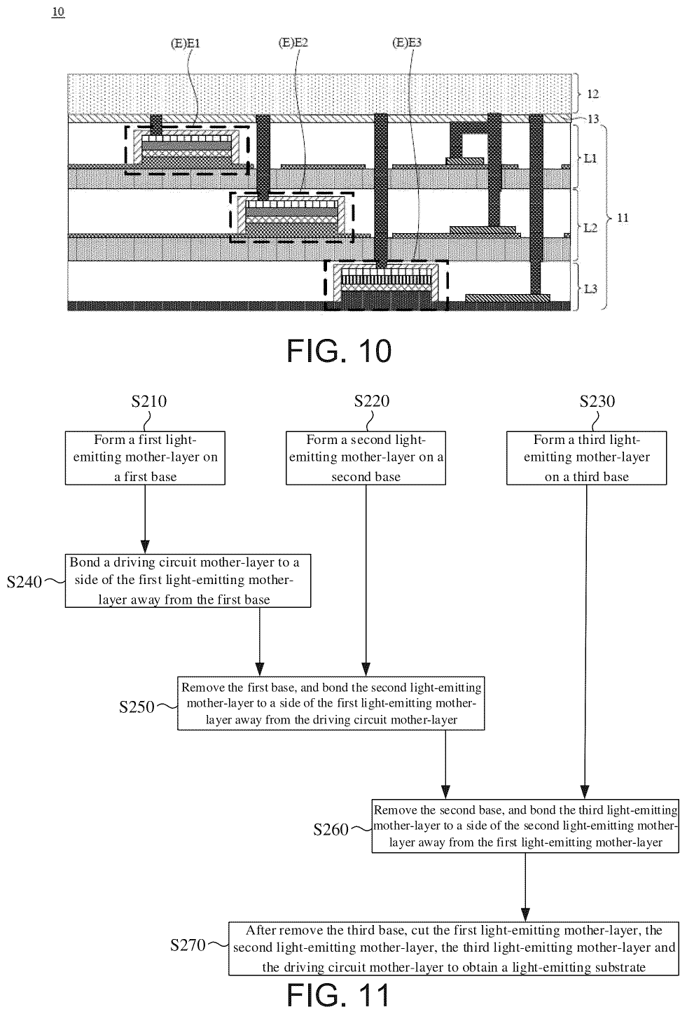

FIG. 4 is a top view of a light-emitting substrate provided in some embodiments of the present disclosure. FIG. 5 is a sectional view taken along the line A-A′ in FIG. 4. FIG. 6 is an equivalent diagram of a pixel circuit in a light-emitting substrate provided in some embodiments of the present disclosure. FIG. 7 is an enlarged view of a first light-emitting device in FIG. 5. FIG. 8 is an enlarged view of a second light-emitting device in FIG. 5. FIG. 9 is an enlarged view of a third light-emitting device in FIG. 5. FIG. 10 is another sectional view taken along the line A-A′ in FIG. 4.

The light-emitting substrate 10 includes a light-emitting layer 11 and a driving circuit layer 12. The light-emitting layer 11 is located on a side of the driving circuit layer 12 and covers a surface of the driving circuit layer 12.

In some examples, an insulating layer 13 is further provided between the light-emitting layer 11 and the driving circuit layer 12, which is not limited here.

The light-emitting layer 11 may include a plurality of light-emitting devices E, and the driving circuit layer 12 may include a plurality of pixel circuits. The plurality of pixel circuits may be arranged in an array on a plane where the driving circuit layer 12 is located. The plurality of pixel circuits may be electrically connected to the plurality of light-emitting devices E in a one-to-one correspondence, so as to provide a respective light-emitting signal to each of the light-emitting devices E. In this way, it may be possible to control the light-emitting brightness of each of the light-emitting devices.

The driving circuit layer 12 may further include a scan control module 121. The scan control module 121 may include a scan driving circuit (Gate Driver on Array (GOA)). The scan driving circuit may be configured to sequentially output scan signals to the plurality of pixel circuits according to the operation timing determined by the second control signal, so as to control the writing of the light-emitting data signals of the plurality of pixel circuits to be performed at different time periods. Each pixel circuit can transmit a written light-emitting data signal to a corresponding light-emitting device E, thereby causing the light-emitting device to emit light.

For example, the pixel circuit includes at least two transistors (denoted by T) and at least one capacitor (denoted by C). For example, the pixel circuit is of a “2T1C” structure, a “6T1C” structure, a “7T1C” structure, a “6T2C” structure, a “7T2C” structure, or the like.

For example, the pixel circuit is of a 7T1C structure; as shown in FIG. 6, the pixel circuit S includes a first transistor T1, a second transistor T2, a third transistor T3, a fourth transistor T4, a fifth transistor T5, a sixth transistor T6, a seventh transistor T7 and a capacitor Cst.

The driving circuit layer 12 may further include a plurality of signal lines. For example, the plurality of signal lines include reset signal lines L-Reset, initialization signal lines L-Vinit, scan signal lines L-Gate, data signal lines L-Data, first power supply line(s) L-VDD, second power supply line(s) L-VSS, and light-emitting control signal lines L-EM.

A control electrode of the first transistor T1 is coupled to the reset signal line L-Reset, a first electrode of the first transistor T1 is coupled to the initialization signal line L-Vinit, and a second electrode of the first transistor T1 is coupled to a first node N1.

A control electrode of the second transistor T2 is coupled to the scan signal line L-Gate, a first electrode of the second transistor T2 is coupled to a third node N3, and a second electrode of the second transistor T2 is coupled to the first node N1.

A control electrode of the third transistor T3 is coupled to the first node N1, a first electrode of the third transistor T3 is coupled to a second node N2, and a second electrode of the third transistor T3 is coupled to the third node N3.

A control electrode of the fourth transistor T4 is coupled to the scan signal line L-Gate, a first electrode of the fourth transistor T4 is coupled to the data signal line L-Data, and a second electrode of the fourth transistor T4 is coupled to the second node N2.

A control electrode of the fifth transistor T5 is coupled to the light-emitting control signal line L-EM, a first electrode of the fifth transistor T5 is coupled to the first power supply line L-VDD, and a second electrode of the fifth transistor T5 is coupled to the second node N2.

A control electrode of the sixth transistor T6 is coupled to the light-emitting control signal line L-EM, a first electrode of the sixth transistor T6 is coupled to the third node N3, and a second electrode of the sixth transistor T6 is coupled to a fourth node N4.

A control electrode of the seventh transistor T7 is coupled to the reset signal line L-Reset, a first electrode of the seventh transistor T7 is coupled to the initialization signal line L-Vinit, and a second electrode of the seventh transistor T7 is coupled to the fourth node N4.

A first electrode plate of the capacitor Cst is coupled to the first power supply line L-VDD, and a second electrode plate of the capacitor Cst is coupled to the first node N1.

With continued reference to FIG. 5, the light-emitting layer 11 may be of a stacked structure. It can be understood that, the light-emitting layer 11 is a light-emitting stacked layer.

As shown in FIG. 5, the light-emitting stacked layer may include a first light-emitting layer L1, a second light-emitting layer L2, and a third light-emitting layer L3 sequentially stacked in a direction Q perpendicular to the driving circuit layer 12. The first light-emitting layer L1 may be a light-emitting layer closest to the driving circuit layer 12 in the light-emitting stacked layer, and the second light-emitting layer L2 is located between the first light-emitting layer L1 and the third light-emitting layer L3.

The first light-emitting layer L1 may include a plurality of first light-emitting devices E1, the second light-emitting layer L2 may include a plurality of second light-emitting devices E2, and the third light-emitting layer L3 may include a plurality of third light-emitting devices E3. Light emitted by the first light-emitting devices E1, light emitted by the second light-emitting devices E2, and light emitted by the third light-emitting devices E3 are of different colors.

For example, the first light-emitting layer L1 includes a plurality of blue light-emitting devices, the second light-emitting layer L2 includes a plurality of green light-emitting devices, and the third light-emitting layer L3 includes a plurality of red light-emitting devices. Of course, the color order of the first light-emitting layer L1, the second light-emitting layer L2 and the third light-emitting layer L3 can also be changed.

For example, the first light-emitting layer L1 includes a plurality of green light-emitting devices, the second light-emitting layer L2 includes a plurality of red light-emitting devices, the third light-emitting layer L3 includes a plurality of blue light-emitting devices. The present disclosure is not limited thereto.

It can be understood that a single blue light-emitting device can be used as a blue sub-pixel, a single green light-emitting device can be used as a green sub-pixel, and a single red light-emitting device can be used as a red sub-pixel. Adjacent blue sub-pixel, green sub-pixel, and red sub-pixel may be used as a pixel unit.

As shown in FIGS. 5 and 7, the first light-emitting layer L1 may include a first semiconductor pattern L1a, a multiple quantum well (MQW) pattern L1b and a second semiconductor pattern L1c that are stacked in sequence away from the driving circuit layer 12. An area of the first semiconductor pattern L1a and an area of the MQW pattern L1b may be approximately equal, and an area of the second semiconductor pattern L1c may be larger than the area of the first semiconductor pattern L1a.

The first semiconductor pattern L1a may include a plurality of first semiconductors E1a that are independent from each other. Similarly, the MQW pattern L1b may include a plurality of MQW bodies E1b that are independent from each other. The number of the first semiconductors Ela may be equal to the number of MQW bodies E1b, and the plurality of first semiconductors Ela are in contact with the plurality of MQW bodies E1b in one-to-one correspondence.

For example, in the first semiconductor Ela and the MQW body E1b that are in contact, an orthographic projection of the first semiconductor Ela on the driving circuit layer 12 substantially coincides with an orthographic projection of the MQW body E1b on the driving circuit layer 12. It can be understood that in the first semiconductor Ela and the MQW body E1b that are in contact, an area of the first semiconductor Ela on the plane where the driving circuit layer 12 is located is approximately equal to an area of the MQW body E1b on the plane where the driving circuit layer 12 is located.

The second semiconductor pattern L1c may include: a plurality of second semiconductors E1c that are independent from each other, and a second semiconductor film CE1 connecting the plurality of second semiconductors E1c. The number of second semiconductors E1c may be equal to the number of MQW bodies E1b, and the plurality of second semiconductors E1c are in contact with the plurality of MQW bodies E1b in one-to-one correspondence.

For example, in the second semiconductor E1c and the MQW body E1b that are in contact, an orthographic projection of the second semiconductor E1c on the driving circuit layer 12 substantially coincides with an orthographic projection of the MQW body E1b on the driving circuit layer 12. It can be understood that in the second semiconductor E1c and the MQW body E1b that are in contact, an area of the second semiconductor E1c on the plane where the driving circuit layer 12 is located is approximately equal to an area of the MQW body E1b on the plane where the driving circuit layer 12 is located.

In this way, two sides of a single MQW body E1b are respectively in contact with a single first semiconductor Ela and a single second semiconductor E1c, so as to together constitute a light-emitting structure of a single first light-emitting device E1. Based on this, second semiconductors E1c of the plurality of first light-emitting devices E1 in the first light-emitting layer L1 are all connected to a second semiconductor film CE1.

For example, the first light-emitting devices E1 are blue light-emitting devices; a material of the first semiconductor pattern L1a may include P-type gallium nitride (GaN) semiconductor material, and a material of the second semiconductor pattern L1c may include N-type gallium nitride (GaN) semiconductor material.

As shown in FIGS. 5 and 7, the first light-emitting layer L1 may further include a first conductive pattern L1d. The first conductive pattern L1d may be located between the first semiconductor pattern La and the driving circuit layer 12.

The first conductive pattern L1d may include a plurality of first conductors AE1 that are independent from each other. The number of the first conductors AE1 may be equal to the number of the first semiconductors Ela, and the plurality of first semiconductors Ela are in contact with the plurality of first conductors AE1 in one-to-one correspondence.

For example, in the first semiconductor Ela and the first conductor AE1 that are in contact, an orthographic projection of the first semiconductor E1a on the driving circuit layer 12 substantially coincides with an orthographic projection of the first conductor AE1 on the driving circuit layer 12. It can be understood that in the first semiconductor Ela and the first conductor AE1 that are in contact, an area of the first semiconductor E1a is approximately equal to an area of the first conductor AE1.

For example, a material of the first conductive pattern L1d may include a transparent conductive material. For example, the material of the first conductive pattern L1d includes indium tin oxide (ITO) or other suitable transparent conductive materials, which is not limited here.

The first conductor AE1 is in contact with the first semiconductor Ela, and can serve as an anode of the first light-emitting device E1 to provide an anode signal to the first semiconductor Ela. Moreover, the second semiconductor film CE1 is in contact with the second semiconductor E1c, and can serve as a cathode of the first light-emitting device E1 to provide a cathode signal to the second semiconductor E1a. In this way, the first conductor AE1, the first semiconductor Ela, the MQW body E1b, the second semiconductor E1c, and the second semiconductor film CE1 together constitute the first light-emitting device E1, and the first light-emitting device E1 can emit light based on the anode signal provided by the pixel circuit and the cathode signal.

The above description that the second semiconductors E1c of the plurality of first light-emitting devices E1 in the first light-emitting layer L1 are connected to a second semiconductor film CE1 can be understood that, the second semiconductors E1c of the plurality of first light-emitting devices E1 in the first light-emitting layer L1 may be of a common cathode structure.

It should be noted that in some other embodiments, the first light-emitting device E1 can be inverted so that the second semiconductor film CE1 is disposed close to the driving circuit layer 12 and the first conductive layer AE1 is disposed far away from the driving circuit layer 12, which is not limited here.

As shown in FIGS. 5 and 7, the first light-emitting layer L1 may further include a first reflective layer L1e. The first reflective layer L1e may include a plurality of first reflective films F1 that are independent from each other. The number of the first reflective films F1 may be equal to the number of the first semiconductors E1a.

The first reflective films F1 have the function of reflecting light. For example, the first reflective films F1 are distributed Bragg reflectors (DBRs).

The first reflective film F1 may be of a stacked structure. For example, the first reflective film F1 includes silicon dioxide (SiO₂) sub-films and titanium oxide (TiO) sub-films, and the SiO₂ sub-films and the TiO sub-films are alternately stacked. The alternating cycle T may meet the requirements of 8≤ T≤10. For example, the alternating cycle T is 8, 9, 10, 11 or 12.

A thickness of a single SiO₂ sub-film in the first reflective film F1 may be approximately equal to one quarter of a wavelength of light emitted by the first light-emitting device E1. For example, if the first light-emitting device E1 emits blue light with a wavelength of 440 nm, the thickness of a single SiO₂ sub-film in the first reflective film F1 may be 110 nm.

Similarly, a thickness of a single TiO sub-film in the first reflective film F1 may be approximately equal to the thickness of a single SiO₂ sub-film, which will not be repeated here.

On this basis, considering an example in which the alternating cycle T of the first reflective film F1 is 10, the thickness of the first reflective film F1 may be 2200 nm.

It should be noted that the thickness of a single SiO₂ sub-film in the first reflective film F1 may refer to a dimension of the SiO₂ sub-film in the direction perpendicular to the driving circuit layer 12 after the driving circuit layer 12 is flattened. Similarly, the thickness of a single TiO sub-film in the first reflective film F1 may refer to a dimension of the TiO sub-film in the direction perpendicular to the driving circuit layer 12 after the driving circuit layer 12 is flattened. Similarly, the thickness of the first reflective film F1 may refer to a dimension of the first reflective film F1 in the direction perpendicular to the driving circuit layer 12 after the driving circuit layer 12 is flattened.

The first reflective film F1 may cover a surface of the first conductor AE1 proximate to the driving circuit layer 12. The first reflective film F1 may further cover side surfaces of the first conductor AE1 perpendicular to the driving circuit layer 12, side surfaces of the first semiconductor Ela perpendicular to the driving circuit layer 12, side surfaces of the MQW body E1b perpendicular to the driving circuit layer 12, and side surfaces of the second semiconductor E1c perpendicular to the driving circuit layer 12.

It can be understood that one first reflective film F1 and the second semiconductor film CE1 together enclose one accommodation space, and the accommodation space accommodates one first conductor AE1, one first semiconductor E1a, one MQW body E1b, and one second semiconductor E1c.

In this way, rays of light emitted by the first light-emitting device E1 toward the driving circuit layer 12 and rays of light parallel to the driving circuit layer 12 will be reflected until all rays of light are emitted from direction(s) toward the second semiconductor film CE1, thereby improving the light-emitting efficiency of each first light-emitting device E1, and in turn improving the light-emitting efficiency of the light-emitting substrate 10.

As shown in FIG. 5, the first light-emitting layer L1 may further include a first filling material pattern L1f covering the first light-emitting devices E1 and the second semiconductor film CE1. The first filling material pattern L1f may be made of an insulating material. For example, the material of the first filling material pattern L1f may include at least one of silicon monoxide (SiO) and high temperature resistant silane resin.

A surface of the first filling material pattern L1f proximate to the driving circuit layer 12 serves as a surface of the first light-emitting layer L1 proximate to the driving circuit layer 12, which provides a flat surface connected to the driving circuit layer 12. In this way, it facilitates the connection between the first light-emitting layer L1 and the driving circuit layer 12, and improves the connection performance between the first light-emitting layer L1 and the driving circuit layer 12.

As shown in FIG. 5, the first light-emitting layer L1 may further include a plurality of first conductive pillars L1g that are independent from each other. A material of the first conductive pillar L1g may include a conductive material; and the conductive material may include suitable metal materials such as copper (Cu), aluminum (AI), and nickel (Ni), or may include other non-metallic materials with good conductive properties.

For example, the number of the first conductive pillars L1g may be approximately equal to 6 times the number of the first light-emitting devices E1.

The plurality of first conductive pillars L1g all extend in the direction perpendicular to the driving circuit layer 12. Extending lengths of the plurality of first conductive pillars L1g are not necessarily equal. For example, one-third of the first conductive pillars L1g have smaller extending lengths, and the remaining two-thirds of the first conductive pillars L1g have larger extending lengths.

The first conductive pillar L1g with a smaller extending length may constitute the first conductive structure D1. An extending length of the first conductive structure D1 is less than a dimension of the first light-emitting layer L1 in the direction perpendicular to the driving circuit layer 12.

For example, a single first light-emitting device E1 is connected to the driving circuit layer 12 through two first conductive structures D1. For example, one first conductive structure D1 connects the anode of the first light-emitting device E1 (i.e., the first conductor AE1) and the driving circuit layer 12; and another first conductive structure D1 connects the cathode of the first light-emitting device E1 (i.e., the second semiconductor film CE1) and the driving circuit layer 12.

The first reflective film F1 may be provided therein with a through hole. The through hole is located between the first conductor AE1 and the driving circuit layer 12. The first conductive structure D1 connected to the anode passes through the through hole to be connected to the anode of the first light-emitting device E1.

In addition, the second semiconductor film CE1 is provided therein with first openings to avoid the two-thirds of the first conductive pillars L1g with larger extending lengths. The first openings penetrate through the second semiconductor film CE1. In this way, the first openings of the second semiconductor film CE1 may prevent the signal on the second semiconductor film CE1 from interfering with the signals on the first conductive pillars L1g, thereby improving the reliability of the light-emitting substrate 10.

As shown in FIG. 5, the anode of the first light-emitting device E1 is closer to the driving circuit layer 12 than the cathode of the first light-emitting device E1. Therefore, a dimension, extending in the direction perpendicular to the driving circuit layer 12, of the first conductive structure D1 connected to the anode is less than a dimension, extending in the direction perpendicular to the driving circuit layer 12, of the first conductive structure D1 connected to the cathode.

As shown in FIG. 5, the first light-emitting layer L1 may further include first auxiliary electrode patterns L1h. The first auxiliary electrode pattern L1h may be of a stacked structure. For example, the first auxiliary electrode pattern L1h may be of a metal stacked structure of Ti/Al/Ti, or a metal stacked structure of Ni/Au.

The first auxiliary electrode pattern L1h has good conductive performance. The first auxiliary electrode pattern L1h may be directly connected to the second semiconductor film CE1 and serve as an auxiliary electrode for the cathode of the first light-emitting device E1 to improve the conductive performance of the cathode of the first light-emitting device E1.

For example, the first auxiliary electrode pattern L1h may be located on a side of the second semiconductor film CE1 proximate to the driving circuit layer 12. An orthographic projection of the first auxiliary electrode pattern L1h on the driving circuit layer 12 is located within an orthographic projection of the second semiconductor film CE1 on the driving circuit layer 12.

The first conductive structure D1 connected to the cathode may be directly connected to the second semiconductor film CE1 instead of directly connected to the first auxiliary electrode pattern L1h. Alternatively, the first conductive structure D1 connected to the cathode may be directly connected to the first auxiliary electrode pattern L1h instead of directly connected to the second semiconductor film CE1.

In some examples, the first auxiliary electrode pattern L1h is a mesh pattern. The first auxiliary electrode pattern L1h in a shape of a mesh can reduce the voltage drop of the signal on the first auxiliary electrode pattern L1h, thus improving the conductive performance of the cathode of the first light-emitting device E1.

It should be noted that the above description is based on the example in which the first auxiliary electrode pattern L1h is connected to the second semiconductor film CE1 to reduce the voltage drop of the cathode signal on the cathode of the first light-emitting device E1. In other embodiments, the first auxiliary electrode pattern L1h may be connected to the first conductor AE1 to reduce the voltage drop of the anode signal on the anode of the first light-emitting device E1. The embodiments of the present disclosure are not limit thereto.

As shown in FIG. 5, the first light-emitting layer L1 may further include a first insulating layer L1i. The first insulating layer L1i may be located on a side of the second semiconductor film CE1 away from the driving circuit layer 12. A surface of the first insulating layer L1i proximate to the driving circuit layer 12 provides a flat surface for the second semiconductor film CE1. A surface of the first insulating layer L1i away from the driving circuit layer 12, serving as a surface of the first light-emitting layer L1 proximate to the second light-emitting layer L2, provides a flat surface connected to the second light-emitting layer L2.

As shown in FIGS. 5 and 8, the second light-emitting layer L2 may include a first semiconductor pattern L2a, a MQW pattern L2b, and a second semiconductor pattern L2c that are stacked in sequence away from the driving circuit layer 12. An area of the first semiconductor pattern L2a and an area of the MQW pattern L2b may be approximately equal, and an area of the second semiconductor pattern L2c may be greater than the area of the first semiconductor pattern L2a.

In addition, the area of the first semiconductor pattern L2a in the second light-emitting layer L2 may be greater than, equal to, or less than the area of the first semiconductor pattern L1a in the first light-emitting layer L1. For example, the relationship between the area of the first semiconductor pattern L2a in the second light-emitting layer L2 and the area of the first semiconductor pattern L1a in the first light-emitting layer L1 may depend on the colors and light-emitting efficiency of the first light-emitting device E1 and the second light-emitting device E2, which is not limited in the present disclosure.

The first semiconductor pattern L2a may include a plurality of first semiconductors E2a that are independent from each other. Similarly, the MQW pattern L2b may include a plurality of MQW bodies E2b that are independent from each other. The number of the first semiconductors E2a may be equal to the number of the MQW bodies E2b, and the plurality of first semiconductors E2a are in contact with the plurality of MQW bodies E2b in one-to-one correspondence.

For example, in the first semiconductor E2a and the MQW body E2b that are in contact, an orthographic projection of the first semiconductor E2a on the driving circuit layer 12 substantially coincides with an orthographic projection of the MQW body E2b on the driving circuit layer 12. It can be understood that in the first semiconductor E2a and the MQW body E2b that are in contact, an area of the first semiconductor E2a on the plane where the driving circuit layer 12 is located is approximately equal to an area of the MQW body E2b on the plane where the driving circuit layer 12 is located.

The second semiconductor pattern L2c may include: a plurality of second semiconductors E2c that are independent from each other, and a second semiconductor film CE2 connecting the plurality of second semiconductors E2c. The number of the second semiconductors E2c may be equal to the number of the MQW bodies E2b, and the plurality of second semiconductors E2c are in contact with the plurality of MQW bodies E2b in one-to-one correspondence.

For example, in the second semiconductor E2c and the MQW body E2b that are in contact, an orthographic projection of the second semiconductor E2c on the driving circuit layer 12 substantially coincides with an orthographic projection of the MQW body E2b on the driving circuit layer 12. It can be understood that in the second semiconductor E2c and the MQW body E2b that are in contact, an area of the second semiconductor E2c on the plane where the driving circuit layer 12 is located is approximately equal to an area of the MQW body E2b on the plane where the driving circuit layer 12 is located.

In this way, two sides of a single MQW body E2b are respectively in contact with a single first semiconductor E2a and a single second semiconductor E2c, so as to together constitute a light-emitting structure of a single second light-emitting device E2. Based on this, second semiconductors E2c of the plurality of second light-emitting devices E2 in the second light-emitting layer L2 are all connected to a single second semiconductor film CE2.

For example, the second light-emitting device E2 is a green light-emitting device, a material of the first semiconductor pattern L2a may include P-type gallium nitride (GaN) semiconductor material, and a material of the second semiconductor pattern L2c may include N-type gallium nitride (GaN) semiconductor material.

As shown in FIGS. 5 and 8, the second light-emitting layer L2 may further include a second conductive pattern L2d. The second conductive pattern L2d may be located between the second semiconductor pattern L2a and the driving circuit layer 12.

The second conductive pattern L2d may include a plurality of second conductors AE2 that are independent from each other. The number of the second conductors AE2 may be equal to the number of the first semiconductors E2a, and the plurality of first semiconductors E2a are in contact with the plurality of second conductors AE2 in one-to-one correspondence.

For example, in the first semiconductor E2a and the second conductor AE2 that are in contact, an orthographic projection of the first semiconductor E2a on the driving circuit layer 12 substantially coincides with an orthographic projection of the second conductor AE2 on the driving circuit layer 12. It can be understood that in the first semiconductor E2a and the second conductor AE2 that are in contact, an area of the first semiconductor E2a is approximately equal to an area of the first conductor AE2.

For example, a material of the second conductive pattern L2d may include a transparent conductive material. For example, the material of the second conductive pattern L2d may include a suitable transparent conductive material such as indium tin oxide (ITO), which is not limited here.

The second conductor AE2 is in contact with the first semiconductor E2a, and may serve as the anode of the second light-emitting device E2 to provide an anode signal to the first semiconductor E2a. In addition, the second semiconductor film CE2 is in contact with the second semiconductor E2c, and may serve as the cathode of the second light-emitting device E2 to provide a cathode signal to the second semiconductor E2c. In this way, the second conductor AE2, the first semiconductor E2a, the MQW body E2b, the second semiconductor E2c, and the second semiconductor film CE2 together constitute the second light-emitting device E2, and the second light-emitting device E2 can emit light based on the anode signal provided by the pixel circuit and the cathode signal.

The above description that the second semiconductors E2c of the plurality of second light-emitting devices E2 in the second light-emitting layer L2 are all connected to one second semiconductor film CE2 can be understood that, the second semiconductors E2c of the plurality of second light-emitting devices E2 in the second light-emitting layer L2 may be of a common cathode structure.

It should be noted that in some other embodiments, the second light-emitting device E2 may be inverted, so that the second semiconductor film CE2 is disposed close to the driving circuit layer 12 and the second conductive layer AE2 is disposed far away from the driving circuit layer 12, which is not limited here.

As shown in FIGS. 5 and 8, the second light-emitting layer L2 may further include a second reflective layer L2e. The second reflective layer L2e may include a plurality of second reflective films F2 that are independent from each other. The number of the second reflective films F2 may be equal to the number of the first semiconductors E2a.

The second reflective films F2 have the function of reflecting light. For example, the second reflective films F2 are DBRs.

The second reflective film F2 may be of a stacked structure. For example, the second reflective film F2 includes SiO₂ sub-films and TiO sub-films, and the SiO₂ sub-films and the TiO sub-films are alternately stacked. The alternating cycle T may meet the requirements of 8≤ T≤10. For example, the alternating cycle T is 8, 9, 10, 11 or 12.

A thickness of a single SiO₂ sub-film in the second reflective film F2 may be approximately equal to one quarter of the wavelength of the light emitted by the second light-emitting device E2. For example, if the second light-emitting device E2 emits green light with a wavelength of 540 nm, then the thickness of a single SiO₂ sub-film in the second reflective film F2 may be 135 nm.

Similarly, a thickness of a single TiO sub-film in the second reflective film F2 may be approximately equal to the thickness of a single SiO₂ sub-film, which will not be repeated here.

On this basis, considering an example in which the alternating cycle T of the second reflective film F2 is equal to 10, the thickness of the second reflective film F2 may be 2700 nm.

It should be noted that the thickness of a single SiO₂ sub-film in the second reflective film F2 may refer to a dimension of the SiO₂ sub-film in the direction perpendicular to the driving circuit layer 12 after the driving circuit layer 12 is flattened. Similarly, the thickness of a single TiO sub-film in the second reflective film F2 may refer to a dimension of the TiO sub-film in the direction perpendicular to the driving circuit layer 12 after the driving circuit layer 12 is flattened. Similarly, the thickness of the second reflective film F2 may refer to a dimension of the second reflective film F2 in the direction perpendicular to the driving circuit layer 12 after the driving circuit layer 12 is flattened.

It can be understood that when the wavelength of the light emitted by the second light-emitting device E2 is greater than the wavelength of the light emitted by the first light-emitting device E1, the thickness of the second reflective film F2 is greater than the thickness of the first reflective film F1.

The second reflective film F2 may cover a surface of the second conductor AE2 proximate to the driving circuit layer 12. The second reflective film F2 may further cover side surfaces of the second conductor AE2 perpendicular to the driving circuit layer 12, side surfaces of the first semiconductor E2a perpendicular to the driving circuit layer 12, side surfaces of the MQW body E2b perpendicular to the driving circuit layer 12, and side surfaces of the second semiconductor E2c perpendicular to the driving circuit layer 12.

It can be understood that one second reflective film F2 and the second semiconductor film CE2 together enclose one accommodation space, and the accommodation space accommodates one second conductor AE2, one first semiconductor E2a, one MQW body E2b, and one second semiconductor E2c.

In this way, rays of light emitted by the second light-emitting device E2 toward the driving circuit layer 12 and rays of light parallel to the driving circuit layer 12 will be reflected until all rays of light are emitted from direction(s) toward the second semiconductor film CE2, thereby improving the light-emitting efficiency of each second light-emitting device E2, and in turn improving the light-emitting efficiency of the light-emitting substrate 10.

As shown in FIG. 5, the second light-emitting layer L2 may further include a second filling material pattern L2f covering the second light-emitting devices E2 and the second semiconductor film CE2. The second filling material pattern L2f may be made of an insulating material. For example, the material of the second filling material pattern L2f may include at least one of SiO and high temperature resistant silane resin.

A surface of the second filling material pattern L2f proximate to the driving circuit layer 12 serves as a surface of the second light-emitting layer L2 proximate to the driving circuit layer 12, which provides a flat surface connected to the first light-emitting layer L1. In this way, it facilitates the connection between the first light-emitting layer L1 and the second light-emitting layer L2, and improves the connection performance between the first light-emitting layer L1 and the second light-emitting layer L2.

As shown in FIG. 5, the second light-emitting layer L2 may further include a plurality of second conductive pillars L2g that are independent from each other. A material of the second conductive pillar L2g may include a conductive material; and the conductive material may include suitable metal materials such as Cu, Al, and Ni, or may include other non-metallic materials with good conductive properties.

For example, the number of the second conductive pillars L2g may be approximately equal to 4 times the number of the second light-emitting devices E2. It can be understood that the number of the second conductive pillars L2g is approximately equal to two-thirds of the number of the first conductive pillars L1g. The plurality of second conductive pillars L2g all extend in the direction perpendicular to the driving circuit layer 12. Extending lengths of the plurality of second conductive pillars L2g are not necessarily equal. For example, half of the second conductive pillars L2g have smaller extending lengths, and the remaining half of the second conductive pillars L2g have larger extending lengths. The extending lengths of the second conductive pillars L2g with smaller extending lengths are less than a dimension of the second light-emitting layer L2 in the direction perpendicular to the driving circuit layer 12.

The plurality of second conductive pillars L2g may be connected to the two-thirds of the first conductive pillars L1g with larger extending lengths in a one-to-one correspondence. A second conductive pillar L2g with a smaller extending length and a first conductive pillar L1g connected thereto may together constitute a second conductive structure D2.

For example, a single second light-emitting device E2 is connected to the driving circuit layer 12 through two second conductive structures D2. For example, one second conductive structure D2 connects the anode of the second light-emitting device E2 (i.e., the second conductor AE2) and the driving circuit layer 12; and another second conductive structure D2 connects the cathode of the second light-emitting device E2 (i.e., the second semiconductor film CE2) and the driving circuit layer 12.

The second reflective film F2 is provided therein with a through hole. The second conductive structure D2 connected to the anode passes through the through hole to be connected to the anode of the second light-emitting device E2.

In addition, the second semiconductor film CE2 is provided therein with second openings to avoid the half of the second conductive pillars L2g with larger extending lengths. The second openings penetrate through the second semiconductor film CE2. In this way, the second openings of the second semiconductor film CE2 may prevent the signal on the second semiconductor film CE2 from interfering with the signals on the second conductive pillars L2g, thereby improving the reliability of the light-emitting substrate 10.

As shown in FIG. 5, the anode of the second light-emitting device E2 is closer to the driving circuit layer 12 than the cathode of the second light-emitting device E2. Therefore, a dimension, extending in the direction perpendicular to the driving circuit layer 12, of the second conductive structure D2 connected to the anode is less than a dimension, extending in the direction perpendicular to the driving circuit layer 12, of the second conductive structure D2 connected to the cathode.

In some examples, the second conductive structure D2 is connected to the first conductive structure D1. For example, as shown in FIG. 5, an auxiliary conductive pillar L1j connecting the second conductive structure D2 and the first conductive structure D1 is formed in the first light-emitting layer L1. For example, an orthographic projection of the auxiliary conductive pillar L1j on the driving circuit layer 12 is located within an orthographic projection of the second semiconductor film CE1 on the driving circuit layer 12.

In this way, when the second conductive structure D2 transmits the cathode signal of the second light-emitting device E2 and the first conductive structure D1 transmits the cathode signal of the first light-emitting device E1, the second light-emitting device E2 and the first light-emitting device E1 share the cathode signal.

On the basis that the second light-emitting device E2 and the first light-emitting device E1 share the cathode signal, the driving circuit layer 12 may simultaneously transmit the cathode signal of the second light-emitting device E2 and the first light-emitting device E1 through one second power signal line L-VSS. Thereby, the number of signal lines inside the driving circuit layer 12 is reduced, the wiring space inside the driving circuit layer 12 is optimized, and the cost of the light-emitting substrate 10 is reduced.

As shown in FIG. 5, the second light-emitting layer L2 may further include second auxiliary electrode patterns L2h. The second auxiliary electrode pattern L2h may be of a stacked structure. For example, the second auxiliary electrode pattern L2h may be of a metal stacked structure of Ti/Al/Ti or a metal stacked structure of Ni/Au.

The second auxiliary electrode pattern L2h has good conductive performance. The second auxiliary electrode pattern L2h may be directly connected to the second semiconductor film CE2 and serve as an auxiliary electrode for the cathode of the second light-emitting device E2 to improve the conductive performance of the cathode of the second light-emitting device E2.

For example, the second auxiliary electrode pattern L2h may be located on a side of the second semiconductor film CE2 proximate to the driving circuit layer 12. An orthographic projection of the second auxiliary electrode pattern L2h on the driving circuit layer 12 is located within an orthographic projection of the second semiconductor film CE2 on the driving circuit layer 12.

In some examples, the orthographic projection of the first auxiliary electrode pattern L1h in the first light-emitting layer L1 on the driving circuit layer 12 may overlap with the orthographic projection of the second auxiliary electrode pattern L2h in the second light-emitting layer L2 on the driving circuit layer 12. The orthographic projection of the first auxiliary electrode pattern L1h on the driving circuit layer 12 may partially overlap with the orthographic projection of the second auxiliary electrode pattern L2h on the driving circuit layer 12; alternatively, the orthographic projection of the first auxiliary electrode pattern L1h on the driving circuit layer 12 is located within the orthographic projection of the second auxiliary electrode pattern L2h on the driving circuit layer 12.

The second conductive structure D2 connected to the cathode may be directly connected to the second semiconductor film CE2 instead of directly connected to the second auxiliary electrode pattern L2h. Alternatively, the second conductive structure D2 connected to the cathode may be directly connected to the second auxiliary electrode pattern L2h instead of directly connected to the second semiconductor film CE2.

In some examples, the second auxiliary electrode pattern L2h may be a mesh pattern. The second auxiliary electrode pattern L2h in a shape of a mesh can reduce the voltage drop of the signal on the second auxiliary electrode pattern L2h, thus improving the conductive performance of the cathode of the second light-emitting device E2.

It should be noted that the above description is based on the example in which the second auxiliary electrode pattern L2h is connected to the second semiconductor film CE2 to reduce the voltage drop of the cathode signal on the cathode of the second light-emitting device E2. In other embodiments, the second auxiliary electrode pattern L2h may be connected to the second conductor AE2 to reduce the voltage drop of the anode signal on the anode of the second light-emitting device E2. The embodiments of the present disclosure are not limit thereto.

As shown in FIG. 5, the second light-emitting layer L2 may further include a second insulating layer L2i. The second insulating layer L2i may be located on a side of the second semiconductor film CE2 away from the driving circuit layer 12. A surface of the second insulating layer L2i proximate to the driving circuit layer 12 provides a flat surface for the second semiconductor film CE2. A surface of the second insulating layer L2i away from the driving circuit layer 12, serving as a surface of the second light-emitting layer L2 proximate to the third light-emitting layer L3, provides a flat surface connected to the third light-emitting layer L3.

As shown in FIGS. 5 and 9, the third light-emitting layer L3 may include a second semiconductor pattern L3c, a MQW pattern L3b, and a first semiconductor pattern L3a that are stacked in sequence away from the driving circuit layer 12. An area of the first semiconductor pattern L3a may be approximately equal to an area of the MQW pattern L3b, and the area of the first semiconductor pattern L3a may be greater than an area of the second semiconductor pattern L3c.

In addition, the area of the first semiconductor pattern L3a in the third light-emitting layer L3 may be greater than, equal to, or less than the area of the first semiconductor pattern L1a in the first light-emitting layer L1. For example, the relationship between the area of the first semiconductor pattern L3a in the third light-emitting layer L3 and the area of the first semiconductor pattern L1a in the first light-emitting layer L1 may depend on the colors and light-emitting efficiency of the first light-emitting device E1 and the third light-emitting device E3, which is not limited in the present disclosure.

The second semiconductor pattern L3c may include a plurality of second semiconductors E3c that are independent from each other. Similarly, the MQW pattern L3b may include a plurality of MQW bodies E3b that are independent from each other. The number of the second semiconductors E3c may be equal to the number of MQW bodies E3b, and the plurality of second semiconductors E3c are in contact with the plurality of MQW bodies E3b in one-to-one correspondence.

For example, in the second semiconductor E3c and the MQW body E2b that are in contact, an orthographic projection of the second semiconductor E3c on the driving circuit layer 12 substantially coincides with an orthographic projection of the MQW body E3b on the driving circuit layer 12. It can be understood that in the second semiconductor E3c and the MQW body E2b that are in contact, an area of the second semiconductor E3c on the plane where the driving circuit layer 12 is located is approximately equal to an area of the MQW body E3b on the plane where the driving circuit layer 12 is located.

The first semiconductor pattern L3a may include: a plurality of first semiconductors E3a that are independent from each other, and a first semiconductor film AE3 connecting the plurality of first semiconductors E3a. The number of the first semiconductors E3a may be equal to the number of MQW bodies E3b, and the plurality of first semiconductors E3c are in contact with the plurality of MQW bodies E2b in one-to-one correspondence.

For example, in the second semiconductor E3c and the MQW body E3b that are in contact, an orthographic projection of the second semiconductor E3c on the driving circuit layer 12 substantially coincides with an orthographic projection of the MQW body E3b on the driving circuit layer 12. It can be understood that in the second semiconductor E3c and the MQW body E3b that are in contact, an area of the second semiconductor E3c on the plane where the driving circuit layer 12 is located is approximately equal to an area of the MQW body E3b on the plane where the driving circuit layer 12 is located.

In this way, two sides of a single MQW body E3b are respectively in contact with a single first semiconductor E3a and a single second semiconductor E3c, and they together constitute a light-emitting structure of a single third light-emitting device E3. Based on this, first semiconductors E3a of the plurality of third light-emitting devices E3 in the third light-emitting layer L3 are all connected to one first semiconductor film AE3. The first semiconductor film AE3 may be of a whole-layer structure covering the driving circuit layer 12.

For example, the third light-emitting device E3 is a red light-emitting device, the first semiconductor pattern L3a may include a P-type gallium phosphide (GaP) semiconductor material, and the second semiconductor pattern L3c may include an N-type aluminum indium phosphide (AlInP) semiconductor material.

As shown in FIGS. 5 and 9, the third light-emitting layer L3 may further include a third conductive pattern L3d. The third conductive pattern L3d may be located between the second semiconductor pattern L3c and the driving circuit layer 12.

The third conductive pattern L3d may include a plurality of third conductors CE3 that are independent from each other. The number of the third conductors CE3 may be equal to the number of the first semiconductors E3c, and the plurality of first semiconductors E3c are in contact with the plurality of third conductors CE3 in one-to-one correspondence.

For example, in the second semiconductor E3c and the third conductor CE3 that are in contact, an orthographic projection of the second semiconductor E3c on the driving circuit layer 12 substantially coincides with an orthographic projection of the third conductor CE3 on the driving circuit layer 12. It can be understood that in the second semiconductor E3c and the third conductor CE3 that are in contact, an area of the second semiconductor E3c is approximately equal to an area of the third conductor CE3.

For example, the third conductive pattern L3d may be of a stacked structure, and the stacked structure may be a metal stacked structure of nickel (Ni)/gold (Au), which is not limited here.

The third conductor CE3 is in contact with the second semiconductor E3c, and may serve as the cathode of the third light-emitting device E3 to provide a cathode signal to the second semiconductor E3c. In addition, the first semiconductor film AE3 is in contact with the first semiconductor E3a, and may serve as the anode of the third light-emitting device E3 to provide an anode signal to the first semiconductor E3c. In this way, the third conductor CE3, the first semiconductor E3a, the MQW body E3b, the second semiconductor E3c, and the first semiconductor film AE3 together constitute the third light-emitting device E3, and the third light-emitting device E3 can emit light based on the cathode signal provided by the pixel circuit and the anode signal.

The above description that the first semiconductors E3a of the plurality of third light-emitting devices E3 in the third light-emitting layer L3 are all connected to one first semiconductor film AE3 can be understood that, the first semiconductors E3a of the plurality of third light-emitting devices E3 in the third light-emitting layer L3 may be of a common anode structure.

It should be noted that in some other embodiments, the third light-emitting device E3 may be inverted so that the first semiconductor film AE3 is disposed close to the driving circuit layer 12 and the third conductive layer CE3 is disposed far away from the driving circuit layer 12, which is not limited here.

As shown in FIGS. 5 and 9, the third light-emitting layer L3 may further include a third reflective layer L3e. The third reflective layer L3e may include a plurality of third reflective films F3 that are independent from each other. The number of the third reflective films F3 may be equal to the number of the second semiconductors E3c.

The third reflective films F3 have the function of reflecting light. For example, the third reflective films F3 are DBRs.

The third reflective film F3 may be of a stacked structure. For example, the third reflective film F3 includes SiO₂ sub-films and TiO sub-films, and the SiO₂ sub-films and the TiO sub-films are alternately stacked. The alternating cycle T may meet the requirements of 8≤ T≤10. For example, the alternating cycle T is 8, 9, 10, 11 or 12.

For example, the alternating cycle T of the first reflective film F1, the alternating cycle T of the second reflective film F2, and the alternating cycle T of the third reflective film F3 are all equal. For example, the alternating cycle T of the first reflective film F1, the alternating cycle T of the second reflective film F2, and the alternating cycle T of the third reflective film F3 are all equal to 10.

A thickness of a single SiO₂ sub-film in the third reflective film F3 may be approximately equal to one quarter of a wavelength of light emitted by the third light-emitting device E3. For example, if the third light-emitting device E3 emits red light with a wavelength of 720 nm, then the thickness of a single SiO₂ sub-film in the third reflective film F3 may be 180 nm.

Similarly, a thickness of a single TiO sub-film in the third reflective film F3 may be approximately equal to the thickness of a single SiO₂ sub-film, which will not be repeated here.

On this basis, considering an example in which the alternating cycle T of the third reflective film F3 is 10, the thickness of the third reflective film F3 may be 3600 nm.

It should be noted that the thickness of a single SiO₂ sub-film in the third reflective film F3 may refer to a dimension of the SiO₂ sub-film in the direction perpendicular to the driving circuit layer 12 after the driving circuit layer 12 is flattened. Similarly, the thickness of a single TiO sub-film in the third reflective film F3 may refer to a dimension of the TiO sub-film in the direction perpendicular to the driving circuit layer 12 after the driving circuit layer 12 is flattened. Similarly, the thickness of the third reflective film F3 may refer to a dimension of the third reflective film F3 in the direction perpendicular to the driving circuit layer 12 after the driving circuit layer 12 is flattened.

It can be understood that when the wavelength of the light emitted by the third light-emitting device E3 is greater than the wavelength of the light emitted by the second light-emitting device E2, the thickness of the third reflective film F3 is greater than the thickness of the second reflective film F2.

The third reflective film F3 may cover a surface of the third conductor CE3 proximate to the driving circuit layer 12. The third reflective film F3 may further cover side surfaces of the third conductor CE3 perpendicular to the driving circuit layer 12, side surfaces of the second semiconductor E3c perpendicular to the driving circuit layer 12, side surfaces of the MQW body E3b perpendicular to the driving circuit layer 12, and side surfaces of the first semiconductor E3a perpendicular to the driving circuit layer 12.

It can be understood that one third reflective film F3 and the first semiconductor film AE3 together constitute one accommodation space, and the accommodation space accommodates one third conductor CE3, one first semiconductor E3a, one MQW body E3b, and one second semiconductor E3c.

In this way, rays of light emitted by the third light-emitting device E3 toward the driving circuit layer 12 and rays of light parallel to the driving circuit layer 12 will be reflected until all rays of light are emitted from direction(s) toward the first semiconductor film AE3, thereby improving the light-emitting efficiency of each third light-emitting device E3, and in turn improving the light-emitting efficiency of the light-emitting substrate 10.

As shown in FIG. 5, the third light-emitting layer L3 may further include a third filling material pattern L3f covering the third light-emitting devices E3 and the first semiconductor film AE3. The third filling material pattern L3f may be made of an insulating material. For example, the material of the third filling material pattern L3f may include at least one of SiO and high temperature resistant silane resin.

A surface of the third filling material pattern L3f proximate to the driving circuit layer 12 serves as a surface of the third light-emitting layer L3 proximate to the second light-emitting layer L2, which provides a flat surface connected to the second light-emitting layer L2. In this way, it facilitates the connection between the second light-emitting layer L2 and the third light-emitting layer L3, and improves the connection performance between the second light-emitting layer L2 and the third light-emitting layer L3.

As shown in FIG. 5, the third light-emitting layer L3 may further include a plurality of third conductive pillars L3g that are independent from each other. A material of the third conductive pillar L3g may include a conductive material. The conductive material may include suitable metal materials such as Cu, Al, and Ni, or may include other non-metallic materials with good conductive properties.

For example, the number of the third conductive pillars L3g may be approximately equal to 2 times the number of the third light-emitting devices E3. It can be understood that the number of the third conductive pillars L3g is approximately equal to half of the number of the second conductive pillars L2g.

The plurality of third conductive pillars L3g all extend in the direction perpendicular to the driving circuit layer 12. Extending lengths of the plurality of third conductive pillars L3g are less than a dimension of the third light-emitting layer L3 in the direction perpendicular to the driving circuit layer 12.

The plurality of third conductive pillars L3g may be connected to the half of the second conductive pillars L2g with larger extending lengths in one-to-one correspondence, and the second conductive pillars L2g with larger extending lengths are connected to the one-third of the first conductive pillars L1g with larger extending lengths in one-to-one correspondence. In this way, a second conductive pillar L2g with a larger extending length, a first conductive pillar L1g with a larger extending length, and a third conductive pillar L3g that are connected to each other may together constitute a third conductive structure D3.

For example, a single third light-emitting device E3 may be connected to the driving circuit layer 12 through two third conductive structures D3. For example, one third conductive structure D3 connects the anode of the third light-emitting device E3 (i.e., the first semiconductor film CE3) and the driving circuit layer 12; and another third conductive structure D3 connects the cathode of the third light-emitting device E3 (i.e., the third conductor CE3) and the driving circuit layer 12.

The third reflective film F3 is provided therein with a through hole. The third conductive structure D3 connected to the cathode passes through the through hole to be connected to the cathode of the third light-emitting device E3.

As shown in FIG. 5, the cathode of the third light-emitting device E3 is closer to the driving circuit layer 12 than the anode of the third light-emitting device E3. Therefore, a dimension, extending in the direction perpendicular to the driving circuit layer 12, of the third conductive structure D3 connected to the cathode is less than a dimension, extending in the direction perpendicular to the driving circuit layer 12, of the third conductive structure D3 connected to the anode.

It can be seen that in FIG. 5, the order of the stacked structures in the third light-emitting device E3 is opposite to both the order of the stacked structures in the first light-emitting device E1 and the order of the stacked structures in the second light-emitting device E2. In some other examples, the order of the stacked structures in the third light-emitting device E3 may be the same as the order of the stacked structures in the first light-emitting device E1 as well as the order of the stacked structures in the second light-emitting device E2, which is not limited in the present disclosure.

As shown in FIG. 5, the third light-emitting layer L3 may further include third auxiliary electrode patterns L3h. The third auxiliary electrode pattern L3h may be of a stacked structure. For example, the third auxiliary electrode pattern L3h may be of a metal stacked structure of Ti/Al/Ti, or a metal stacked structure of Ni/Au.

The third auxiliary electrode pattern L3h has good conductive performance. The third auxiliary electrode pattern L3h may be directly connected to the first semiconductor film AE3 and serve as an auxiliary electrode for the anode of the third light-emitting device E3 to improve the conductive performance of the anode of the third light-emitting device E3.

For example, the third auxiliary electrode pattern L3h may be located on a side of the first semiconductor film AE3 proximate to the driving circuit layer 12. An orthographic projection of the third auxiliary electrode pattern L3h on the driving circuit layer 12 is located within an orthographic projection of the first semiconductor film AE3 on the driving circuit layer 12.

In some examples, the orthographic projection of the second auxiliary electrode pattern L2h in the second light-emitting layer L2 on the driving circuit layer 12 may overlap with the orthographic projection of the third auxiliary electrode pattern L3h in the third light-emitting layer L3 on the driving circuit layer 12. The orthographic projection of the second auxiliary electrode pattern L2h on the driving circuit layer 12 may partially overlap with the orthographic projection of the third auxiliary electrode pattern L3h on the driving circuit layer 12; alternatively, the orthographic projection of the second auxiliary electrode pattern L2h on the driving circuit layer 12 is located within the orthographic projection of the third auxiliary electrode pattern L3h on the driving circuit layer 12.

The third conductive structure D3 connected to the anode may be directly connected to the first semiconductor film AE3 instead of directly connected to the third auxiliary electrode pattern L3h. Alternatively, the third conductive structure D3 connected to the anode may be directly connected to the third auxiliary electrode pattern L3h instead of directly connected to the first semiconductor film AE3.

In some examples, the third auxiliary electrode pattern L3h may be a mesh pattern. The third auxiliary electrode pattern L3h in a shape of a mesh can reduce the voltage drop of the signal on the third auxiliary electrode pattern L3h, thus improving the conductive performance of the anode of the third light-emitting device E3.

It should be noted that the above description is based on the example in which the third auxiliary electrode pattern L3h is connected to the first semiconductor film AE3 to reduce the voltage drop of the anode signal on the anode of the third light-emitting device E3. In other embodiments, the third auxiliary electrode pattern L3h may be connected to the third conductor CE3 to reduce the voltage drop of the cathode signal on the cathode of the third light-emitting device E3. The embodiments of the present disclosure are not limit thereto.

As shown in FIG. 5, the third light-emitting layer L3 may further include a third insulating layer L3i. The third insulating layer L3i may be located on a side of the first semiconductor film AE3 away from the driving circuit layer 12. A surface of the third insulating layer L3i proximate to the driving circuit layer 12 provides a flat surface for the first semiconductor film AE3. A surface of the third insulating layer L3i away from the driving circuit layer 12, serving as a surface of the third light-emitting layer L3 away from the driving circuit layer 12, provides a flat surface for connection with other structures (e.g., an encapsulation layer).

As shown in FIG. 5, a plurality of conductive bumps 14 may be provided on a surface of the driving circuit layer 12 away from the light-emitting stacked layer 11. The conductive bumps 14 may be electrically connected to the plurality of pixel circuits in the driving circuit layer 12.

The conductive bumps 14 are used to be electrically connected to the timing control circuit 21 and the driving module 22 on the circuit board, so that the driving circuit layer 12 receives the second control signal provided by the timing control circuit 21 and the light-emitting data signals provided by the driving module 22. Thus, the scan control module 121 outputs scan signals based on the second control signal, to control the plurality of pixel circuits to enter writing phases at different time periods, and the pixel circuit which enters the writing phase can perform the writing of a corresponding light-emitting data signal.

As shown in FIGS. 5 and 10, an orthographic projection of the first light-emitting device E1 on the driving circuit layer 12, an orthographic projection of the second light-emitting device E2 on the driving circuit layer 12, and an orthographic projection of the third light-emitting device E3 on the driving circuit layer 12 do not necessarily coincide with each other, which means that the three do not coincide with each other, or the three partially coincide with each other.

As shown in FIG. 5, the orthographic projection of the first light-emitting device E1 in the first light-emitting layer L1 on the driving circuit layer 12, the orthographic projection of the second light-emitting device E2 in the second light-emitting layer L2 on the driving circuit layer 12, and the orthographic projection of the third light-emitting device E3 in the third light-emitting layer L3 on the driving circuit layer 12 do not coincide with each other.

In this way, the light emitted by the first light-emitting device E1, the light emitted by the second light-emitting device E2, and the light emitted by the third light-emitting device E3 do not affect each other, which can improve the light-emitting efficiency of the light-emitting substrate 10.

As shown in FIG. 10, among the orthographic projection of the first light-emitting device E1 in the first light-emitting layer L1 on the driving circuit layer 12, the orthographic projection of the second light-emitting device E2 in the second light-emitting layer L2 on the driving circuit layer 12, and the orthographic projection of the third light-emitting device E3 in the third light-emitting layer L3 on the driving circuit layer 12, at least two of the three may partially coincide with each other.

For example, the orthographic projection of the first light-emitting device E1 on the driving circuit layer 12 may partially coincide with the orthographic projection of the second light-emitting device E2 on the driving circuit layer 12; or, the orthographic projection of the third light-emitting device E3 on the driving circuit layer 12 may partially coincide with the orthographic projection of the second light-emitting device E2 on the driving circuit layer 12; or, the orthographic projection of the first light-emitting device E1 on the driving circuit layer 12 may partially coincide with the orthographic projection of the third light-emitting device E3 on the driving circuit layer 12; or, the orthographic projection of the second light-emitting device E2 on the driving circuit layer 12 partially coincides with the orthographic projection of the first light-emitting device E1 on the driving circuit layer 12, and partially coincides with the orthographic projection of the third light-emitting device E3 on the driving circuit layer 12.

In this way, the arrangement density of the first light-emitting devices E1, the second light-emitting devices E2 and the third light-emitting devices E3 in the light-emitting substrate 10 can be increased, thereby improving the resolution of the display apparatus.

FIG. 11 shows a method for manufacturing a light-emitting substrate provided in some embodiments of the present disclosure.

Some embodiments of the present disclosure further provide a method for manufacturing a light-emitting substrate. As shown in FIG. 11, the method for manufacturing the light-emitting substrate may include steps S210 to S270.

In S210, a first light-emitting mother-layer is formed on a first base. The first light-emitting mother-layer includes a plurality of first light-emitting devices.

The first base may be a silicon base, or the first base may be a sapphire base. For ease of understanding, the following description will be illustrated by taking an example where the first base is a silicon base.

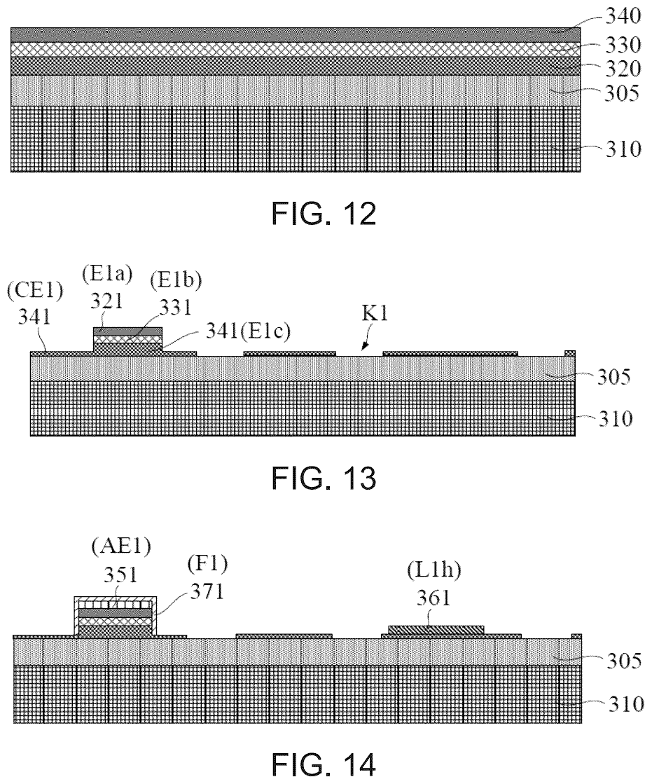

As shown in FIG. 12, a first semiconductor material layer 320, a MQW material layer 330 and a second semiconductor material layer 340 are sequentially deposited on the silicon base 310. The first semiconductor material layer 320, the MQW material layer 330 and the second semiconductor material layer 340 are each of a whole-layer structure.

In some examples, before forming the second semiconductor material layer 340 on the silicon base 310, a first buffer layer 305 may be deposited on the silicon base 310. In the case where the first semiconductor material layer is made of an N-type semiconductor material, the first buffer layer 305 may be made of an N-type semiconductor buffer material.

As shown in FIG. 13, the first semiconductor material layer 320 is patterned to form a first semiconductor mother-layer 321. The first semiconductor mother-layer 321 may include a plurality of first semiconductors Ela that are independent from each other.

The MQW material layer 330 is patterned to form a MQW mother-layer 331. The MQW mother-layer 331 may include a plurality of MQW bodies E1b that are independent from each other. An orthographic projection of the MQW mother-layer 331 on the silicon base may substantially coincide with an orthographic projection of the first semiconductor mother-layer 321 on the silicon base.

The second semiconductor material layer 340 is partially patterned to form a second semiconductor mother-layer 341. The second semiconductor mother-layer 341 may include: a plurality of second semiconductors E1c that are independent from each other, and a second semiconductor film CE1 connecting the plurality of second semiconductors E1c. The second semiconductor film CE1 includes a plurality of first openings K1, and the plurality of first openings K1 are used to avoid first conductive pillars that are formed subsequently. An orthographic projection of the MQW mother-layer 331 on the silicon base 310 may be located within an orthographic projection of the second semiconductor mother-layer 341 on the silicon base 310.

As shown in FIG. 14, a first conductive material layer covering the first semiconductor mother-layer 321 and the silicon base 310 is formed. The first conductive material layer is patterned to form a first conductive mother-layer 351. The first conductive mother-layer 351 may include a plurality of first conductors AE1 that are independent from each other. An orthographic projection of the first conductive mother-layer 351 on the silicon base 310 may substantially coincide with an orthographic projection of the first semiconductor mother-layer 321 on the silicon base 310.

A first auxiliary conductive material layer covering the second semiconductor film CE1 is formed. The first auxiliary conductive material layer may be of a stacked structure, which may include a metal stacked structure of Ti/Al/Ti.

The first auxiliary conductive material layer is patterned to form a first auxiliary electrode mother-layer 361. The first auxiliary electrode mother-layer 361 may include a plurality of first auxiliary electrode patterns L1h. An orthographic projection of the first auxiliary electrode mother-layer 361 on the silicon base 310 is located within an orthographic projection of the second semiconductor film CE1 on the silicon base 310.

It should be noted that the first conductive mother-layer 351 may be formed before the first auxiliary electrode mother-layer 361 is formed; alternatively, the first auxiliary electrode mother-layer 361 may be formed before the first conductive mother-layer 351 is formed. The present disclosure is not limited thereto.

A first reflective material layer covering the first conductive mother-layer 351 and the silicon base 310 is formed. The first reflective material layer may be of a stacked structure. For example, the first reflective material layer includes SiO₂ sub-films and TiO sub-films, and the SiO₂ sub-films and TiO sub-films are alternately stacked. The alternating cycle T may meet the requirements of 8≤ T≤10. For example, the alternating cycle T is 8, 9, 10, 11 or 12.

The first reflective material layer is patterned to form a first reflective mother-layer 371. The first reflective mother-layer 371 may include a plurality of first reflective films F1 that are independent from each other.

The first reflective film F1 may cover a surface of the first conductor AE1 away from the silicon base 310. The first reflective film F1 may further cover side surfaces of the first conductor AE1 perpendicular to the silicon base 310, side surfaces of the first semiconductor Ela perpendicular to the silicon base 310, side surfaces of the MQW body E1b perpendicular to the silicon base 310, and side surfaces of the second semiconductor E1c perpendicular to the silicon base 310.

A through hole may be formed in the first reflective film F1 using an etching process, and the through hole is located on a side of the first conductor AE1 away from the silicon base 310, to avoid a first conductive pillar that is subsequently formed. It should be noted that the first reflective mother-layer 371 may be formed before the first auxiliary electrode mother-layer 361 is formed; alternatively, the first auxiliary electrode mother-layer 361 may be formed before the first reflective mother-layer 371 is formed. The present disclosure is not limited thereto.

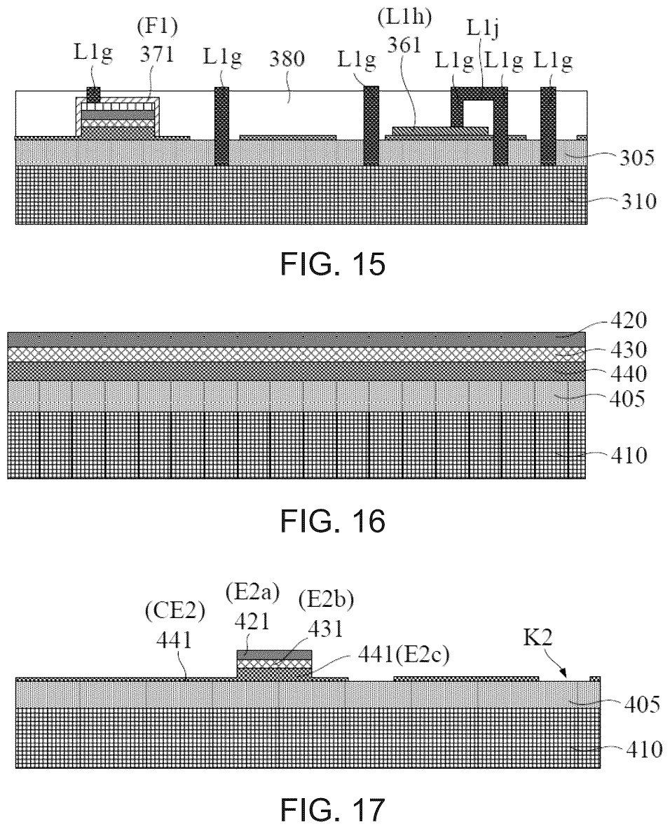

As shown in FIG. 15, after the first reflective mother-layer 371 and the first auxiliary electrode mother-layer 361 are fabricated, a filling material is deposited to form a first filling material layer 380 covering the silicon base 310, the first reflective mother-layer 371 and the first auxiliary electrode mother-layer 361. The filling material may be at least one of SiO and high temperature resistant silane resin.

Next, a chemical mechanical polishing (CMP) process may be performed on a surface of the first filling material layer 380 away from the silicon base 310 to obtain the first filling material layer 380 whose surface away from the silicon base 310 is flat.

A plurality of first channels are formed using an etching process, which may be a dry etching process. Each first channel penetrates through the first filling material layer 380. One-sixth of the plurality of first channels are communicated with through holes formed in the first reflective mother-layer 371; another one-sixth of the first channels are connected to the first auxiliary electrode mother-layer 361; and the remaining two-thirds of the first channels penetrate through both the first filling material layer 380 and the first buffer layer to be communicated with the silicon base 310. The remaining two-thirds of the first channels may pass through first openings K1 formed in the second semiconductor film CE1.

The first channels may be formed using the Bosch process. The Bosch process can prevent or weaken the etching in a direction parallel to an extending direction of the silicon base 310, thereby reducing the opening size of the first channel, facilitating the reduction of the spacing between the first light-emitting devices in the first light-emitting mother-layer, and improving the arrangement density of the first light-emitting devices in the first light-emitting mother-layer.

After the plurality of first channels are formed, a conductive metal layer covering at least an inner wall of a first channel may be formed in the first channel to form a first conductive pillar L1g. The conductive metal layer may only cover the inner wall of the first channel, or may fill the first channel, which is not limited here. The material of the conductive metal layer may include Cu, Ni, tungsten (W) and other metals with good conductivity, which is not limited here.

The conductive metal layer may be formed using the Damascene process.

The Damascene process does not require the etching of the metal layer. Since the dry etching of the metal (such as copper) is difficult, the Damascene process can improve the fabrication efficiency of conductive metal layer.

In this way, among a plurality of first conductive pillars L1g in the first light-emitting layer, one-sixth of the first conductive pillars L1g pass through the through holes formed in the first reflective mother-layer 371 to be connected to first conductors AE1; and another one-sixth of the first conductive pillars L1g are connected to first auxiliary electrode patterns L1h in the first auxiliary electrode mother-layer 361.

In some examples, auxiliary channels are also etched in the first filling material layer 380. A first auxiliary channel is communicated with a first channel that is communicated with a first auxiliary electrode pattern L1h and a first channel that penetrates through both the first filling material layer 380 and the first buffer layer. On this basis, the second semiconductor film CE1 may not be provided therein with a corresponding opening to avoid a first channel that penetrates through both the first filling material layer 380 and the first buffer layer.

The conductive metal layer covering at least the inner wall of the first channel is formed in the first channel to form the first conductive pillar L1g, and at the same time, an auxiliary conductive pillar L1j covering at least an inner wall of an auxiliary channel may be formed. The auxiliary conductive pillar L1j is connected to a first conductive pillar L1g that is connected to a first auxiliary electrode pattern L1h and a first conductive pillar L1g that is connected to a first channel penetrating through both the first filling material layer 380 and the first buffer layer 305.

In some embodiments, the relevant fabrication steps of the first auxiliary electrode mother-layer 361 may be omitted. In this embodiment, the first conductive pillars L1g may be directly connected to the second semiconductor film CE1.

In some embodiments, the relevant fabrication steps of the first reflective mother-layer 371 may be omitted. In this embodiment, the first filling material layer 380 may directly cover the surface of the first conductor AE1 away from the silicon base 310, the side surfaces of the first conductor AE1 perpendicular to the silicon base 310, the side surfaces of the first semiconductor Ela perpendicular to the silicon base 310, the side surfaces of the MQW body E1b perpendicular to the silicon base 310, and the side surfaces of the second semiconductor E1c perpendicular to the silicon base 310.

In step S220, a second light-emitting mother-layer is formed on a second base. The second light-emitting mother-layer includes a plurality of second light-emitting devices.

The second base may be a silicon base, or the second base may be a sapphire base. For ease of understanding, the following description will be illustrated by taking an example where the second base is a silicon base 410.

As shown in FIG. 16, a first semiconductor material layer 420, a MQW material layer 430 and a second semiconductor material layer 440 are sequentially deposited on the silicon base 410. The first semiconductor material layer 420, the MQW material layer 430 and the second semiconductor material layer 440 are each of a whole-layer structure.

In some examples, before forming the second semiconductor material layer 440 on the silicon base 410, a second buffer layer 405 may be deposited on the silicon base 410. In the case where the first semiconductor material is made of an N-type semiconductor material, the second buffer layer 405 may be made of an N-type semiconductor buffer material.

As shown in FIG. 17, the first semiconductor material layer 420 is patterned to form a first semiconductor mother-layer 421. The first semiconductor mother-layer 421 may include a plurality of first semiconductors E2a that are independent from each other.

The MQW material layer 430 is patterned to form a MQW mother-layer 431.

The MQW mother-layer 431 may include a plurality of MQW bodies E2b that are independent from each other. An orthographic projection of the MQW mother-layer 431 on the silicon base may substantially coincide with an orthographic projection of the first semiconductor mother-layer 421 on the silicon base.

The second semiconductor material layer 440 is partially patterned to form a second semiconductor mother-layer 441. The second semiconductor mother-layer 441 may include: a plurality of second semiconductors E2c that are independent from each other, and a second semiconductor film CE2 connecting the plurality of second semiconductors E2c. The second semiconductor film CE2 includes a plurality of second openings K2, and the plurality of second openings K2 are used to avoid second conductive pillars that are formed subsequently. An orthographic projection of the MQW mother-layer 431 on the silicon base 410 is located within an orthographic projection of the second semiconductor mother-layer 441 on the silicon base 410.

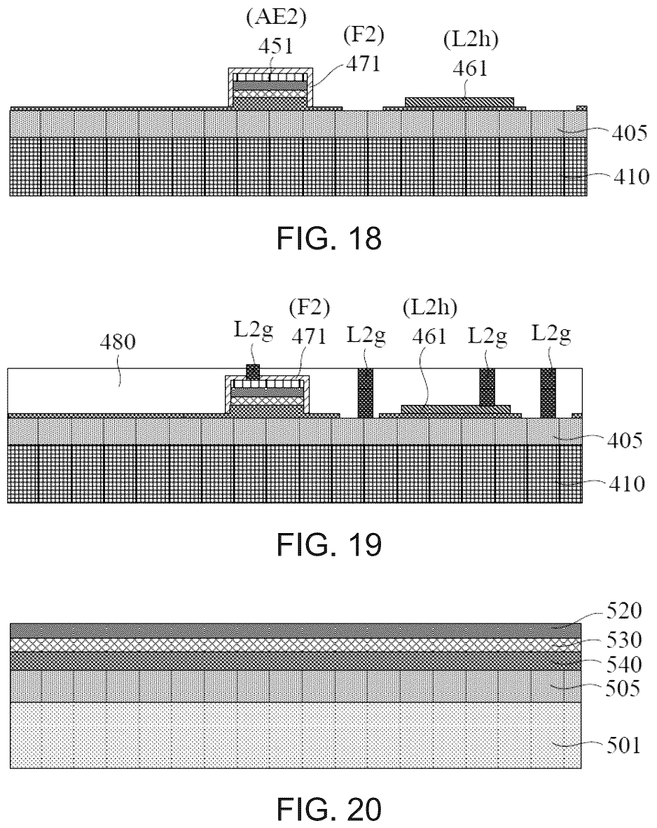

As shown in FIG. 18, a second conductive material layer covering the first semiconductor mother-layer 421 and the silicon base 410 is formed. The second conductive material layer is patterned to form a second conductive mother-layer 451. The second conductive mother-layer 451 may include a plurality of second conductors AE2 that are independent from each other. An orthographic projection of the second conductive mother-layer 451 on the silicon base 410 may substantially coincide with an orthographic projection of the first semiconductor mother-layer 421 on the silicon base 410.

A second auxiliary conductive material layer covering the second semiconductor film CE2 is formed. The second auxiliary conductive material layer may be of a stacked structure, which may include a metal stacked structure of Ti/Al/Ti.

The second auxiliary conductive material layer is patterned to form a second auxiliary electrode mother-layer 461. The second auxiliary electrode mother-layer 461 may include a plurality of second auxiliary electrode patterns L2h. An orthographic projection of the second auxiliary electrode mother-layer 461 on the silicon base 410 is located within an orthographic projection of the second semiconductor film CE2 on the silicon base 410.

It should be noted that the second conductive mother-layer 451 may be formed before the second auxiliary electrode mother-layer 461 is formed; alternatively, the second auxiliary electrode mother-layer 461 may be formed before the second conductive mother-layer 451 is formed. The present disclosure is not limited thereto.

A second reflective material layer covering the second conductive mother-layer 451 and the silicon base 410 is formed. The second reflective material layer may be of a stacked structure. For example, the second reflective material layer includes SiO₂ sub-films and TiO sub-films, and the SiO₂ sub-films and TiO sub-films are alternately stacked. The alternating cycle T may meet the requirements of 8≤ T≤10. For example, the alternating cycle T is 8, 9, 10, 11 or 12.

The second reflective material layer is patterned to form a second reflective mother-layer 471. The second reflective mother-layer 471 may include a plurality of second reflective films F2 that are independent from each other.

The second reflective film F2 may cover a surface of the second conductor AE2 away from the silicon base 410. The second reflective film F2 may further cover side surfaces of the second conductor AE2 perpendicular to the silicon base 410, side surfaces of the first semiconductor E2a perpendicular to the silicon base 410, side surfaces of the MQW body E2b perpendicular to the silicon base 410, and side surfaces of the second semiconductor E2c perpendicular to the silicon base 410.

A through hole may be formed in the second reflective film F2 using an etching process, and the through hole is located on a side of the second conductor AE2 away from the silicon base 410, to avoid a second conductive pillar that is subsequently formed.

It should be noted that the second reflective mother-layer 471 may be formed before the second auxiliary electrode mother-layer 461 is formed; alternatively, the second auxiliary electrode mother-layer 461 may be formed before the second reflective mother-layer 471 is formed. The present disclosure is not limited thereto.

As shown in FIG. 19, after the second reflective mother-layer 471 and the second auxiliary electrode mother-layer 461 are fabricated, a filling material is deposited to form a second filling layer 480 covering the silicon base 410, the second reflective mother-layer 471 and the second auxiliary electrode mother-layer 461. The filling material may be at least one of SiO and high temperature resistant silane resin.

Next, a CMP process may be performed on a surface of the second filling material layer 480 away from the silicon base 410 to obtain the second filling material layer 480 whose surface away from the silicon base 410 is flat.

A plurality of second channels are formed using an etching process. The number of the second channels may be two-thirds of the number of the first channels. The etching process may be a dry etching process. Each second channel penetrates through the second filling material layer 480. One quarter of the plurality of second channels are communicated with through holes formed in the second reflective mother-layer 471; another one quarter of the first channels are connected to the second auxiliary electrode mother-layer 461; and the remaining half of the second channels penetrate through both the second filling material layer 480 and the second buffer layer 405 to be communicated with the silicon base 410. The remaining half of the second channels may pass through second openings K2 formed in the second semiconductor film CE2.

The second channels may be formed using the Bosch process. The Bosch process can prevent or weaken the etching in a direction parallel to an extending direction of the silicon base 410, thereby reducing the opening size of the second channel, facilitating the reduction of the spacing between the second light-emitting devices in the second light-emitting mother-layer, and improving the arrangement density of the second light-emitting devices in the second light-emitting mother-layer.

After the plurality of second channels are formed, a conductive metal layer covering at least an inner wall of a second channel may be formed in the second channel to form a second conductive pillar L2g. The conductive metal layer may only cover the inner wall of the second channel, or may fill the second channel, which is not limited here. The material of the conductive metal layer may include Cu, Ni, W and other metals with good conductivity, which is not limited here.

The conductive metal layer may be formed using the Damascene process.

The Damascene process does not require the etching of the metal layer. Since the dry etching of the metal (such as copper) is difficult, the Damascene process can improve the fabrication efficiency of conductive metal layer.

In this way, among a plurality of second conductive pillars L2g in the second light-emitting layer, one quarter of the second conductive pillars L2g pass through the through holes formed in the second reflective mother-layer 471 to be connected to second conductors AE2; and another one quarter of the second conductive pillars L2g are connected to second auxiliary electrode patterns L2h in the second auxiliary electrode mother-layer 461.

In some embodiments, the relevant fabrication steps of the second auxiliary electrode mother-layer 461 may be omitted. In this embodiment, the second conductive pillars L2g may be directly connected to the second semiconductor film CE2.

In some embodiments, the relevant fabrication steps of the second reflective mother-layer 471 may be omitted. In this embodiment, the second filling material layer 480 may directly cover the surface of the second conductor AE2 away from the silicon base 410, the side surfaces of the second conductor AE2 perpendicular to the silicon base 410, the side surfaces of the first semiconductor E2a perpendicular to the silicon base 410, the side surfaces of the MQW body E2b perpendicular to the silicon base 410, and the side surfaces of the second semiconductor E2c perpendicular to the silicon base 410.

In step S230, a third light-emitting mother-layer is formed on a third base. The third light-emitting mother-layer includes a plurality of third light-emitting devices.

In FIG. 20, a second semiconductor material layer 540, a MQW material layer 530 and a first semiconductor material layer 520 are sequentially deposited on a gallium arsenide base 501. The first semiconductor material layer 520, the MQW material layer 530 and the second semiconductor material layer 540 are each of a whole-layer structure.

In some examples, before forming the first semiconductor material layer 520 on the gallium arsenide base 501, a third buffer layer 505 may be deposited on the gallium arsenide base 501. A material of the third buffer layer 505 may include a gallium arsenide buffer material.

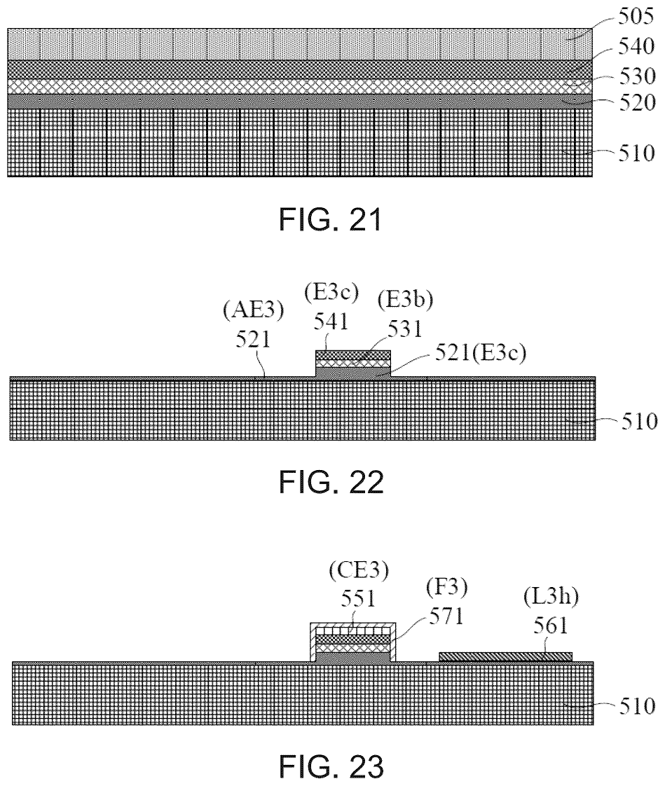

Since the gallium arsenide base 501 has poor mechanical properties and absorbs red light, patterning the first semiconductor material layer 520, the MQW material layer 530 and the second semiconductor material layer 540 on the gallium arsenide base 501 can easily cause defects. In view of this, after forming the first semiconductor material layer 520, the MQW material layer 530 and the second semiconductor material layer 540 on the gallium arsenide base 501, the gallium arsenide base 501 and the third buffer layer 505, the first semiconductor material layer 520, the MQW material layer 530 and the second semiconductor material layer 540 that are located on the gallium arsenide base 501 are inverted and transferred to the third base 510, and the gallium arsenide base 501 is removed, as shown in FIG. 21. In this case, the second semiconductor material layer 540 may be in direct contact with the third base 510.

Next, the third buffer layer 505 may be removed on the third base 510.

The third base may be a silicon base, or the third base may be a sapphire substrate. For ease of understanding, the following description will be illustrated by taking an example where the third base is a silicon base 510.

As shown in FIG. 22, the second semiconductor material layer 540 is patterned to form a second semiconductor mother-layer 541. The second semiconductor mother-layer 541 may include a plurality of second semiconductors E3c that are independent from each other.

The MQW material layer 530 is patterned to form a MQW mother-layer 531.

The MQW mother-layer 531 may include a plurality of MQW bodies E3b that are independent from each other. An orthographic projection of the MQW mother-layer 531 on the silicon base 510 may substantially coincide with an orthographic projection of the second semiconductor mother-layer 541 on the silicon base 510.

The first semiconductor material layer 520 is partially patterned to form a first semiconductor mother-layer 521. The first semiconductor mother-layer 521 may include: a plurality of first semiconductors E3a that are independent from each other, and a first semiconductor film AE3 connecting the plurality of first semiconductors E3a. The first semiconductor film AE3 may be of a whole-layer structure covering the silicon base 510. An orthographic projection of the MQW mother-layer 531 on the silicon base 510 is located within an orthographic projection of the first semiconductor mother-layer 521 on the silicon base 510.

As shown in FIG. 23, a third conductive material layer covering the second semiconductor mother-layer 541 and the silicon base 510 is formed. The third conductive material layer is patterned to form a third conductive mother-layer 551. The third conductive mother-layer 551 may include a plurality of third conductors CE3 that are independent from each other. An orthographic projection of the third conductive mother-layer 551 on the silicon base 510 may substantially coincide with an orthographic projection of the second semiconductor mother-layer 541 on the silicon base 510.

A third auxiliary conductive material layer covering the first semiconductor film AE3 is formed. The third auxiliary conductive material layer may be of a stacked structure, which may include a metal stacked structure of Ti/Al/Ti.

The third auxiliary conductive material layer is patterned to form a third auxiliary electrode mother-layer 561. The third auxiliary electrode mother-layer 561 may include a plurality of third auxiliary electrode patterns L3h. An orthographic projection of the third auxiliary electrode mother-layer 561 on the silicon base 510 is located within an orthographic projection of the first semiconductor film AE3 on the silicon base 510.

It should be noted that the third conductive mother-layer 551 may be formed before the third auxiliary electrode mother-layer 561 is formed; alternatively, the third auxiliary electrode mother-layer 561 may be formed before the third conductive mother-layer 551 is formed. The present disclosure is not limited thereto.

A third reflective material layer covering the third conductive mother-layer 551 and the silicon base 510 is formed. The third reflective material layer may be of a stacked structure. For example, the third reflective material layer includes SiO₂ sub-films and TiO sub-films, and the SiO₂ sub-films and TiO sub-films are alternately stacked. The alternating cycle T may meet the requirements of 8≤ T≤10. For example, the alternating cycle T is 8, 9, 10, 11 or 12.

The third reflective material layer is patterned to form a third reflective mother-layer 571. The third reflective mother-layer 571 may include a plurality of third reflective films F3 that are independent from each other.

The third reflective film F3 may cover a surface of the third conductor CE3 away from the silicon base 510. The third reflective film F3 may further cover side surfaces of the third conductor CE3 perpendicular to the silicon base 510, side surfaces of the second semiconductor E3c perpendicular to the silicon base 510, side surfaces of the MQW body E3b perpendicular to the silicon base 510, side surfaces of the first semiconductor E3a perpendicular to the silicon base 510.

A through hole may be formed in the third reflective film F3 using an etching process, and the through hole is located on a side of the third conductor CE3 away from the silicon base 510, to avoid a second conductive pillar that is subsequently formed.

It should be noted that the third reflective mother-layer 571 may be formed before the third auxiliary electrode mother-layer 561 is formed; alternatively, the third auxiliary electrode mother-layer 561 may be formed before the third reflective mother-layer 571 is formed. The present disclosure is not limited thereto.

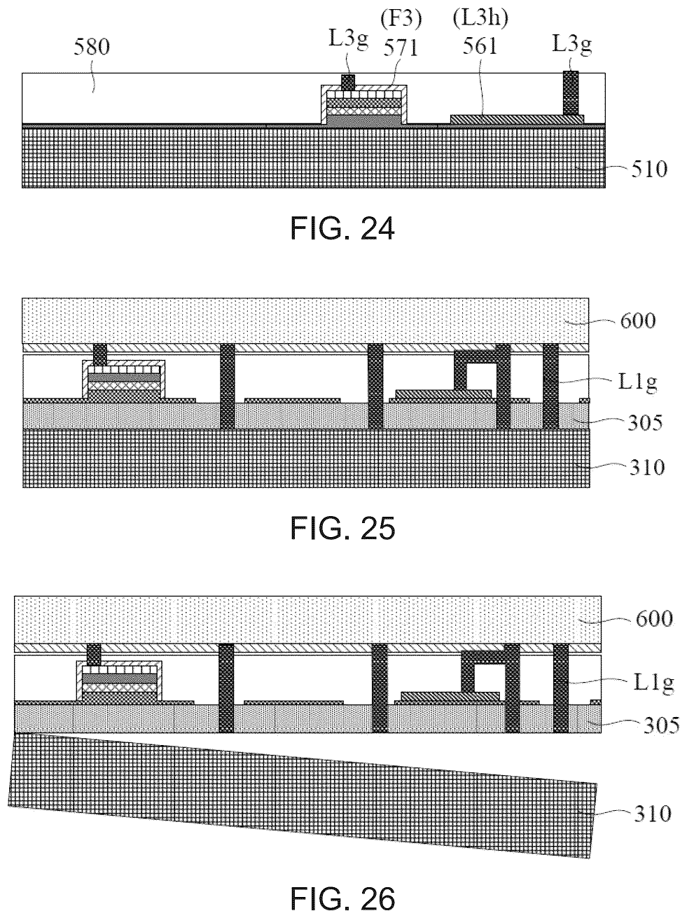

As shown in FIG. 24, after the third reflective mother-layer 571 and the third auxiliary electrode mother-layer 561 are fabricated, a filling material is deposited to form a third filling layer 580 covering the silicon base 510, the third reflective mother-layer 571 and the third auxiliary electrode mother-layer 561. The filling material may be at least one of SiO and high temperature resistant silane resin.

Next, a CMP process may be performed on a surface of the third filling material layer 580 away from the silicon base 510 to obtain the third filling material layer 580 whose surface away from the silicon base 510 is flat.

A plurality of third channels are formed using an etching process. The number of the third channels may be one-third of the number of the first channels. It can be understood that the number of the third channels may be half of the number of the second channels. The etching process may be a dry etching process. Each third channel penetrates through the third filling material layer 580. A half of the plurality of third channels are communicated with through holes formed in the third reflective mother-layer 571; and another half of the third channels are connected to the third auxiliary electrode mother-layer 561.

The third channels may be formed using the Bosch process. The Bosch process can prevent or weaken the etching in a direction parallel to an extending direction of the silicon base 510, thereby reducing the opening size of the third channel, facilitating the reduction of the spacing between the third light-emitting devices in the third light-emitting mother-layer, and improving the arrangement density of the third light-emitting devices in the third light-emitting mother-layer.

After forming the plurality of third channels, a conductive metal layer covering at least an inner wall of a third channel may be formed in the third channel to form a third conductive pillar L3g. The conductive metal layer may only cover the inner wall of the third channel, or may fill the third channel, which is not limited here. The material of the conductive metal layer may include Cu, Ni, W and other metals with good conductivity, which is not limited here.

The conductive metal layer may be formed using the Damascene process. The Damascene process does not require the etching of the metal layer. Since the dry etching of the metal (such as copper) is difficult, the Damascene process can improve the fabrication efficiency of conductive metal layer.

In this way, among the plurality of third conductive pillars L3g in the third light-emitting layer, half of the third conductive pillars L3g pass through the through holes formed in the third reflective mother-layer 571 to be connected to third conductors CE3; and another half of the third conductive pillars L3g are connected to third auxiliary electrode patterns L3h in the third auxiliary electrode mother-layer 561.

In some embodiments, the relevant fabrication steps of the third auxiliary electrode mother-layer 561 may be omitted. In this embodiment, the third conductive pillars L3g may be directly connected to the first semiconductor film AE3.

In some embodiments, the relevant fabrication steps of the third reflective mother-layer 571 may be omitted. In this embodiment, the third filling material layer 580 may directly cover the surface of the third conductor CE3 away from the silicon base 510, the side surfaces of the third conductor CE3 perpendicular to the silicon base 510, the side surfaces of the second semiconductor E3c perpendicular to the silicon base 510, the side surfaces of the MQW body E3b perpendicular to the silicon base 510, the side surfaces of the first semiconductor E3a perpendicular to the silicon base 510.

It should be noted that steps S210, S220 and S230 may be performed at different time period, or may be performed at the same time, which is not limited here. In step S240: a driving circuit mother-layer is bonded to a side of the first light-emitting mother-layer away from the first base. The driving circuit mother-layer includes a plurality of pixel circuits and a common electrode, and the plurality of pixel circuits are respectively coupled to the plurality of first light-emitting devices.

As shown in FIG. 25, the driving circuit mother-layer 600 exposes a plurality of conductive contact points, and the number of the conductive contact points may be equal to the number of the first conductive pillars L1g in the first light-emitting mother-layer. Half of the plurality of conductive contact points are connected to the plurality of pixel circuits in the driving circuit mother-layer 600 in one-to-one correspondence, and another half of the conductive contact points may be connected to the second power supply line(s) L-VSS in the driving circuit mother-layer 600.

After the CMP, the surface of the first light-emitting mother-layer away from the first base exposes ends of the plurality of first conductive pillars L1g. By aligning and bonding the plurality of exposed conductive contact points of the driving circuit mother-layer 600 with the plurality of exposed first conductive pillars L1g of the first light-emitting mother-layer, the plurality of conductive contact points of the driving circuit mother-layer 600 are bonded to the plurality of first conductive pillars L1g of the first light-emitting mother-layer.

The material of the conductive contact points and the material of the first conductive pillars L1g may both include metal copper. The conductive contact points and the first conductive pillars L1g may be bonded using thermo-compression bonding, and the bonding accuracy may be within a range of 1 μm.

In step S250, the first base is removed, and the second light-emitting mother-layer is bonded to the side of the first light-emitting mother-layer away from the driving circuit mother-layer. The second light-emitting mother-layer includes the plurality of second light-emitting devices, and the plurality of second light-emitting devices are respectively coupled to the plurality of pixel circuits.

As shown in FIG. 26, a laser lift off (LLO) process may be used to remove the first base 310 connected to the first light-emitting mother-layer.

After the first base is removed, the CMP process may be used to thin the first buffer layer 305 to ensure that ends of the two-thirds of the first conductive pillars L1g with larger extending lengths are exposed, and in turn improve the reliability of this part of the first conductive pillars L1g to be subsequently bonded to the second conductive pillars L2g in the second light-emitting mother-layer.

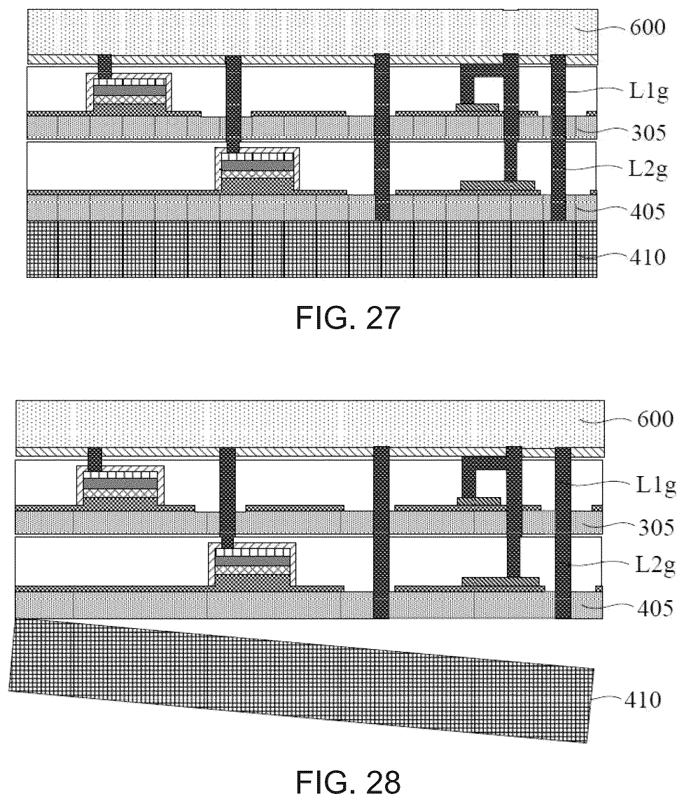

As shown in FIG. 27, after the CMP, the surface of the second light-emitting mother-layer away from the second base exposes ends of the plurality of second conductive pillars L2g. By aligning and bonding the ends of the plurality of exposed first conductive pillars L1g in the first light-emitting mother-layer with the plurality of exposed second conductive pillars L2g in the second light-emitting mother-layer, two-thirds of the first conductive pillars L1g in the first light-emitting mother-layer are bonded to the plurality of second conductive pillars L2g of the second light-emitting mother-layer.

The material of the second conductive pillars L2g and the material of the first conductive pillars L1g may both include metal copper. The second conductive pillars L2g and the first conductive pillars L1g may be bonded using thermo-compression bonding, and the bonding accuracy may be within a range of 1 μm.

In step S260, the second base is removed, and the third light-emitting mother-layer is bonded to a side of the second light-emitting mother-layer away from the first light-emitting mother-layer. The third light-emitting mother-layer includes the plurality of third light-emitting devices, and the plurality of third light-emitting devices are respectively coupled to the plurality of pixel circuits.

As shown in FIG. 28, a laser lift off (LLO) process may be used to remove the second base connected to the second light-emitting mother-layer.

After the second base is removed, the CMP process may be used to thin the second buffer layer 405 to ensure that ends of half of the second conductive pillars L2g with larger extending lengths are exposed, and in turn improve the reliability of this part of the second conductive pillars L2g to be subsequently bonded to the third conductive pillars L3g in the third light-emitting mother-layer.

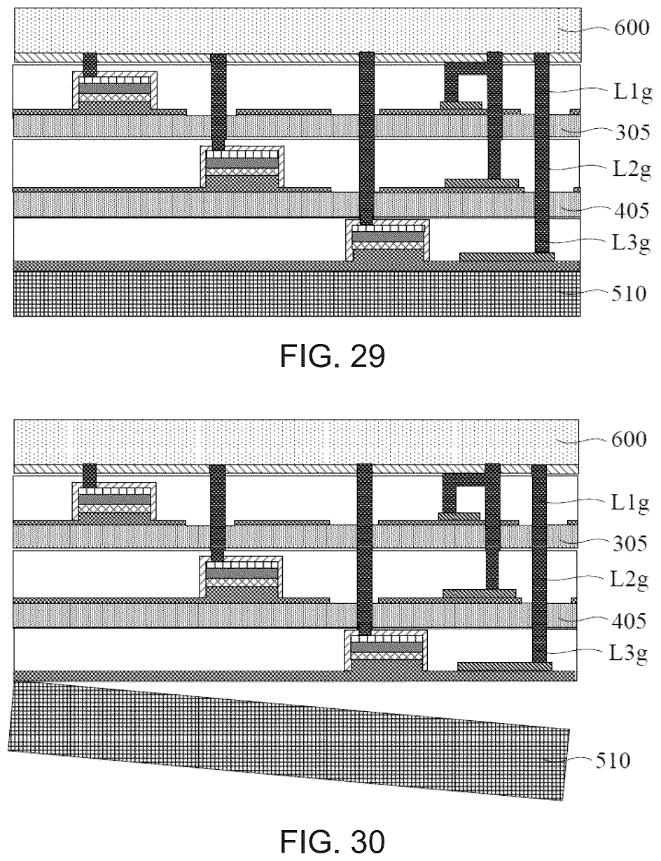

As shown in FIG. 29, after the CMP, the surface of the third light-emitting mother-layer away from the third base exposes ends of the plurality of third conductive pillars L3g. By aligning and bonding the ends of the plurality of exposed second conductive pillars L2g in the second light-emitting mother-layer with the plurality of exposed third conductive pillars L3g in the third light-emitting mother-layer, half of the second conductive pillars L2g in the second light-emitting mother-layer are bonded to the plurality of third conductive pillars L3g in the third light-emitting mother-layer.

The material of the third conductive pillars L3g and the material of the second conductive pillars L2g may both include metal copper. The third conductive pillars L3g and the second conductive pillars L2g may be bonded using thermo-compression bonding, and the bonding accuracy may be within a range of 1 μm.

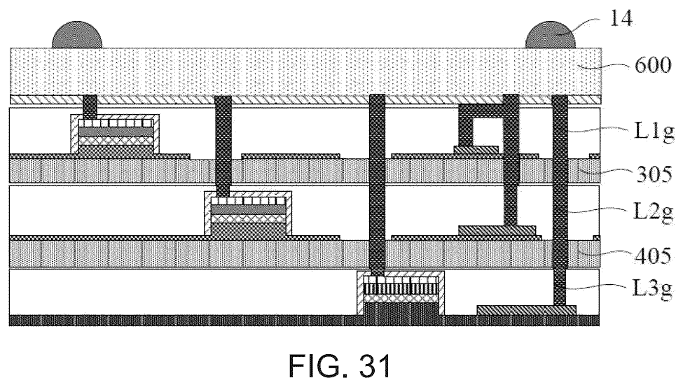

In step S270: after the third substrate is removed, the first light-emitting mother-layer, the second light-emitting mother-layer, the third light-emitting mother-layer and the driving circuit mother-layer are cut to obtain the light-emitting substrate. As shown in FIG. 30, a laser lift off (LLO) process may be used to remove the third base connected to the third light-emitting mother-layer.

As shown in FIG. 31, after the third base is removed, a plurality of conductive bumps 14 may be formed on the surface of the driving circuit layer away from the first light-emitting mother-layer. The conductive bumps 14 may be electrically connected to the plurality of pixel circuits in the driving circuit layer. The conductive bumps 14 are used to be electrically connected to the timing control circuit and the driving module on the circuit board, so that the driving circuit layer receives the second control signal provided by the timing control circuit and the light-emitting data signals provided by the driving module.

The number of the conductive bumps 14 is less than the number of the pixel circuits in the driving circuit layer.

Next, the first light-emitting mother-layer, the second light-emitting mother-layer, the third light-emitting mother-layer and the driving circuit mother-layer are cut according to the size of the light-emitting substrate, so as to obtain the light-emitting substrate as described above.

The foregoing descriptions are merely specific implementation manners of the present disclosure, but the protection scope of the present disclosure is not limited thereto, any changes or replacements that a person skilled in the art could conceive of within the technical scope of the present disclosure shall be included in the protection scope of the present disclosure. Therefore, the protection scope of the present disclosure shall be subject to the protection scope of the claims.

What is claimed is:

1. A light-emitting substrate, comprising:
a driving circuit layer including a plurality of pixel circuits;
a first light-emitting layer located on a side of the driving circuit layer, wherein the first light-emitting layer includes a plurality of first light-emitting devices, and the plurality of first light-emitting devices are respectively coupled to the plurality of pixel circuits;
a second light-emitting layer located on a side of the first light-emitting layer away from the driving circuit layer, wherein the second light-emitting layer includes a plurality of second light-emitting devices, and the plurality of second light-emitting devices are respectively coupled to the plurality of pixel circuits; and
a third light-emitting layer located on a side of the second light-emitting layer away from the driving circuit layer, wherein the third light-emitting layer includes a plurality of third light-emitting devices, and the plurality of third light-emitting devices are respectively coupled to the plurality of pixel circuits; wherein
a color of light emitted by the first light-emitting devices, a color of light emitted by the second light-emitting devices, and a color of light emitted by the third light-emitting devices are different from each other; and
an orthographic projection of a first light-emitting device on the driving circuit layer, an orthographic projection of a second light-emitting device on the driving circuit layer, an orthographic projection of a third light-emitting device on the driving circuit layer do not necessarily coincide with each other.

2. The light-emitting substrate according to claim 1, wherein the first light-emitting layer includes first auxiliary electrode patterns, and an anode or cathode of the first light-emitting device is coupled to a first auxiliary electrode pattern; and/or
the second light-emitting layer includes second auxiliary electrode patterns, and an anode or cathode of the second light-emitting device is coupled to a second auxiliary electrode pattern.

3. The light-emitting substrate according to claim 1, wherein the third light-emitting layer includes third auxiliary electrode patterns, and an anode or cathode of the third light-emitting device is coupled to a third auxiliary electrode pattern.

4. The light-emitting substrate according to claim 2, wherein the third light-emitting layer includes third auxiliary electrode patterns, and an anode or cathode of the third light-emitting device is coupled to a third auxiliary electrode pattern.

5. The light-emitting substrate according to claim 4, wherein the light-emitting substrate comprises the first auxiliary electrode patterns, the second auxiliary electrode patterns, and the third auxiliary electrode patterns; and
an area of the third auxiliary electrode pattern is greater than an area of the second auxiliary electrode pattern, and the area of the second auxiliary electrode pattern is greater than an area of the first auxiliary electrode pattern.

6. The light-emitting substrate according to claim 4, wherein the light-emitting substrate comprises the first auxiliary electrode patterns, the second auxiliary electrode patterns, and the third auxiliary electrode patterns; and
an orthographic projection of the second auxiliary electrode pattern on the driving circuit layer at least partially coincides with an orthographic projection of the first auxiliary electrode pattern on the driving circuit layer; and/or
an orthographic projection of the third auxiliary electrode pattern on the driving circuit layer at least partially coincides with the orthographic projection of the second auxiliary electrode pattern on the driving circuit layer.

7. The light-emitting substrate according to claim 1, wherein
the first light-emitting layer includes 3N first conductive pillars, the second light-emitting layer includes 2N second conductive pillars, the third light-emitting layer includes N third conductive pillars, and the first conductive pillars, the second conductive pillars and the third conductive pillars all extend in a direction perpendicular to the driving circuit layer;
N first conductive pillars constitute N first conductive structures, and each of the first conductive structures is connected to the driving circuit layer and a first light-emitting device;
another N first conductive pillars and N second conductive pillars are connected in one-to-one correspondence and together constitute N second conductive structures, and each of the second conductive structures is connected to the driving circuit layer and a second light-emitting device;
remaining N first conductive pillars and another N second conductive pillars are connected in one-to-one correspondence, and the another N second conductive pillars and the N third conductive pillars are connected in one-to-one correspondence; the remaining N first conductive pillars, the another N second conductive pillars and the N third conductive pillars together constitute N third conductive structures; and each of the third conductive structures is connected to the driving circuit layer and a third light-emitting device.

8. The light-emitting substrate according to claim 1, wherein
the first light-emitting layer includes first reflective films, and a first reflective film covers side surfaces of the first light-emitting device perpendicular to the driving circuit layer and a surface of the first light-emitting device proximate to the driving circuit layer; and/or
the second light-emitting layer includes second reflective films, and a second reflective film covers side surfaces of the second light-emitting device perpendicular to the driving circuit layer and a surface of the second light-emitting device proximate to the driving circuit layer.

9. The light-emitting substrate according to claim 1, wherein the third light-emitting layer includes third reflective films, and a third reflective film covers side surfaces of the third light-emitting device perpendicular to the driving circuit layer and a surface of the third light-emitting device proximate to the driving circuit layer.

10. The light-emitting substrate according to claim 8, wherein the third light-emitting layer includes third reflective films, and a third reflective film covers side surfaces of the third light-emitting device perpendicular to the driving circuit layer and a surface of the third light-emitting device proximate to the driving circuit layer.

11. The light-emitting substrate according to claim 10, wherein the light-emitting substrate comprises the first reflective films, the second reflective films, and the third reflective films;
a wavelength of the color of the light emitted by the first light-emitting devices is less than a wavelength of the color of the light emitted by the second light-emitting devices, and the wavelength of the color of the light emitted by the second light-emitting devices is less than a wavelength of the color of the light emitted by the third light-emitting devices;
a thickness of the first reflective film is less than a thickness of the second reflective film, and the thickness of the second reflective film is less than a thickness of the third reflective film.

12. The light-emitting substrate according to claim 1, wherein
an anode of the first light-emitting device is located on a side of a cathode of the first light-emitting device proximate to the driving circuit layer, and/or an anode of the second light-emitting device is located on a side of a cathode of the second light-emitting device proximate to the driving circuit layer; and
a cathode of the third light-emitting device is located on a side of an anode of the third light-emitting device proximate to the driving circuit layer.

13. The light-emitting substrate according to claim 1, wherein the orthographic projection of the first light-emitting device on the driving circuit layer overlaps with the orthographic projection of the second light-emitting device on the driving circuit layer; and/or the orthographic projection of the second light-emitting device on the driving circuit layer overlaps with the orthographic projection of the third light-emitting device on the driving circuit layer; or
the orthographic projection of the third light-emitting device on the driving circuit layer overlaps with the orthographic projection of the first light-emitting device on the driving circuit layer.

14. The light-emitting substrate according to claim 1, wherein the orthographic projection of the first light-emitting device on the driving circuit layer overlaps with the orthographic projection of the second light-emitting device on the driving circuit layer; and/or the orthographic projection of the second light-emitting device on the driving circuit layer overlaps with the orthographic projection of the third light-emitting device on the driving circuit layer; and
the orthographic projection of the third light-emitting device on the driving circuit layer overlaps with the orthographic projection of the first light-emitting device on the driving circuit layer.

15. A display apparatus, comprising:
the light-emitting substrate according to claim 1; and
a circuit board coupled to the driving circuit layer of the light-emitting substrate.

16. A method for manufacturing a light-emitting substrate, the method comprising:
forming a first light-emitting mother-layer on a first base, the first light-emitting mother-layer including a plurality of first light-emitting devices;
forming a second light-emitting device mother-layer on a second base, the second light-emitting mother-layer including a plurality of second light-emitting devices;
forming a third light-emitting mother-layer on a third base, the third light-emitting mother-layer including a plurality of third light-emitting devices;
bonding a driving circuit mother-layer to a side of the first light-emitting mother-layer away from the first base, wherein the driving circuit mother-layer includes a plurality of pixel circuits, and the plurality of pixel circuits are respectively coupled to the plurality of first light-emitting devices;
removing the first base, and bonding the second light-emitting mother-layer to a side of the first light-emitting mother-layer away from the driving circuit mother-layer, wherein the plurality of second light-emitting devices are respectively coupled to the plurality of pixel circuits;
removing the second base, and bonding the third light-emitting mother-layer to a side of the second light-emitting mother-layer away from the first light-emitting mother-layer, wherein the plurality of third light-emitting devices are respectively coupled to the plurality of pixel circuits; and
after removing the third base, cutting the first light-emitting mother-layer, the second light-emitting mother-layer, the third light-emitting mother-layer and the driving circuit mother-layer to obtain the light-emitting substrate.

17. The method according to claim 16, wherein forming the first light-emitting mother-layer on the first base includes:
providing the first base;
sequentially forming a first semiconductor mother-layer, a multiple quantum well (MQW) mother-layer and a second semiconductor mother-layer on the first base in a direction away from the first base, wherein the first semiconductor mother-layer includes a plurality of first semiconductors that are independent from each other, the MQW mother-layer includes a plurality of MQW bodies that are independent from each other, and the second semiconductor mother-layer includes a plurality of second semiconductors that are independent from each other and a second semiconductor film connecting the plurality of second semiconductors; and
forming a first conductive mother-layer on a side of the second semiconductor mother-layer away from the first base, the first conductive mother-layer including a plurality of first conductors that are independent from each other;
wherein a first conductor, a first semiconductor, a MQW body, a second semiconductor and the second semiconductor film constitute a first light-emitting device.

18. The method according to claim 17, wherein after forming the first light-emitting mother-layer, the method further comprises:
forming a first reflective material layer covering the first conductive mother-layer and the first base; and
patterning the first reflective material layer to obtain a first reflective mother-layer, wherein the first reflective mother-layer includes a plurality of first reflective films that are independent from each other, and a first reflective film covers a surface of the first conductor away from the first base, side surfaces of the first conductor perpendicular to the first base, side surfaces of the first semiconductor perpendicular to the first base, and side surfaces of the MQW body perpendicular to the first base, and side surfaces of the second semiconductor perpendicular to the first base.

19. The method according to claim 17, wherein after forming the second semiconductor mother-layer, the method further comprises:
forming a first auxiliary electrode material layer covering the second semiconductor film; and
patterning the first auxiliary electrode material layer to obtain first auxiliary electrode patterns, orthographic projections of the first auxiliary electrode patterns on the first base being located within an orthographic projection of the second semiconductor film on the first base.

20. The method according to claim 17, wherein after forming the plurality of first light-emitting devices that are spaced apart from each other, the method further comprises:
forming a first filling material layer covering the plurality of first light-emitting devices, a surface of the first filling material layer away from the first base being a flat surface;
forming a plurality of first channels penetrating through the first filling material layer; and
forming a first conductive pillar covering at least an inner wall of each first channel.
